(19) United States
(12) Patent Application Publication
(10) Pub. No.: US 2025/0343206 A1
(43) Pub. Date: Nov. 6, 2025

(54) SEMICONDUCTOR PACKAGE STRUCTURES AND METHODS OF FORMING SAME

(71) Applicant: Taiwan Semiconductor Manufacturing Co., Ltd., Hsinchu (TW)

(72) Inventors: Yen-Liang Lin, Taichung City (TW); Tzuan-Horng Liu, Longtan Township (TW); An-Jhih Su, Taoyuan City (TW)

(21) Appl. No.: 19/268,493

(22) Filed: Jul. 14, 2025

Related U.S. Application Data
(63) Continuation of application No. 18/412,779, filed on Jan. 15, 2024.
(60) Provisional application No. 63/582,934, filed on Sep. 15, 2023.

(51) Int. Cl. H01L 25/065; H01L 21/56; H01L 21/768; H01L 23/00; H01L 23/31; H01L 23/48; H01L 23/522; H01L 25/10

(52) U.S. Cl. CPC H01L 25/0657; H01L 21/56; H01L 21/76898; H01L 23/3107; H01L 23/481; H01L 23/5226; H01L 24/11; H01L 24/16; H01L 24/81; H01L 25/105; H01L 24/48; H01L 2224/11; H01L 2224/16145; H01L 2224/16225; H01L 2224/48227; H01L 2224/81

(57) ABSTRACT

An embodiment is a method including forming a first die, the forming including forming through vias in a first substrate. The method also includes forming a first redistribution structure over the through vias and the first substrate, the first redistribution structure being electrically coupled to the through vias. The method also includes forming a first set of die connectors over and electrically coupled to the first redistribution structure, the first set of die connectors being on a first side of the first substrate. The method also includes bonding the first die to a second die. The method also includes encapsulating the first die with a first encapsulant. The method also includes forming a second set of die connectors over and electrically coupled to the first set of die connectors, the first and second sets of die connectors forming stacked die connectors.

### PRIORITY CLAIM AND CROSS-REFERENCE

This application is a continuation of U.S. patent application Ser. No. 18/412,779, filed Jan. 15, 2024, entitled “Semiconductor Package Structures and Methods of Forming Same,” which claims the benefit of U.S. Provisional Application No. 63/582,934, filed on Sep. 15, 2023, which applications are hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (POP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 illustrate a cross-sectional views of an integrated circuit die, in accordance with some embodiments.

FIGS. 3 through 12B illustrate cross-sectional views of intermediate steps for forming a package component, in accordance with some embodiments.

FIGS. 13 through 26 illustrate cross-sectional views of intermediate steps for forming a package structure, in accordance with some embodiments.

FIGS. 27 and 28 illustrate formation and implementation of device stacks, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments discussed herein may be discussed in a specific context, namely a via or connector structure that can be integrated into a device (e.g., a chip or die) or a package (e.g., an integrated fan-out (InFO) package structure). The via or connector structure includes stacked vias and multiple passivation layers to allow for the ability to test the dies and chips of the package structure while also allowing for a lower chip package interaction (CPI) risk of the package structure. For example, the stacked vias and multiple polymer layers allow for each of the chips of a chiplet structure to be tested and be known good dies (KGDs) while providing protection for the chips during and after the testing.

Further, the teachings of this disclosure are applicable to any stacked vias or connectors and multiple passivation layers where these structures can allow for the needed testing and probing while keeping the CPI risk low. Other embodiments contemplate other applications, such as different package types or different configurations that would be readily apparent to a person of ordinary skill in the art upon reading this disclosure. It should be noted that embodiments discussed herein may not necessarily illustrate every component or feature that may be present in a structure. For example, multiples of a component may be omitted from a figure, such as when discussion of one of the components may be sufficient to convey aspects of the embodiment. Further, method embodiments discussed herein may be discussed as being performed in a particular order; however, other method embodiments may be performed in any logical order.

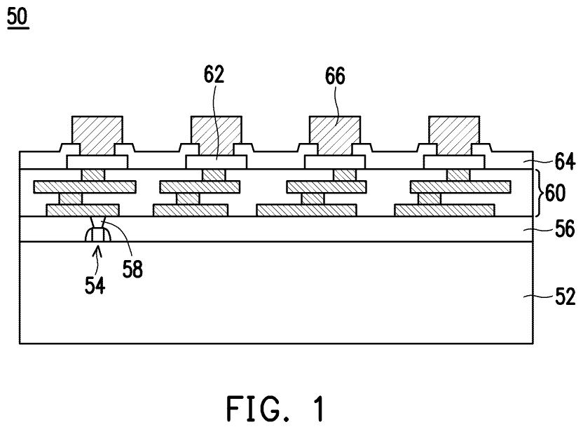

FIG. 1 illustrates a cross-sectional view of an integrated circuit die 50 in accordance with some embodiments. The integrated circuit die 50 will be packaged in subsequent processing to form an integrated circuit package. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The integrated circuit die 50 may be formed in a wafer, which may include different device regions that are singulated in subsequent steps to form a plurality of integrated circuit dies. The integrated circuit die 50 may be processed according to applicable manufacturing processes to form integrated circuits. For example, the integrated circuit die 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 1), sometimes called a front side, and an inactive surface (e.g., the surface facing downwards in FIG. 1), sometimes called a back side.

Devices (represented by a transistor) 54 may be formed at the front surface of the semiconductor substrate 52. The devices 54 may be active devices (e.g., transistors, diodes, etc.), capacitors, resistors, etc. An inter-layer dielectric (ILD) 56 is over the front surface of the semiconductor substrate 52. The ILD 56 surrounds and may cover the devices 54. The ILD 56 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Conductive C plugs 58 extend through the ILD 56 to electrically and physically couple the devices 54. For example, when the devices 54 are transistors, the conductive plugs 58 may couple the gates and source/drain regions of the transistors. Source/drain region(s) may refer to a source or a drain, individually or collectively dependent upon the context. The conductive plugs 58 may be formed of tungsten, cobalt, nickel, copper, silver, gold, aluminum, the like, or combinations thereof. An interconnect structure 60 is over the ILD 56 and conductive plugs 58. The interconnect structure 60 interconnects the devices 54 to form an integrated circuit. The interconnect structure 60 may be formed by, for example, metallization patterns in dielectric layers on the ILD 56. The metallization patterns include metal lines and vias formed in one or more low-k dielectric layers. The metallization patterns of the interconnect structure 60 are electrically coupled to the devices 54 by the conductive plugs 58.

The integrated circuit die 50 further includes pads 62, such as aluminum pads, to which external connections are made. The pads 62 are on the active side of the integrated circuit die 50, such as in and/or on the interconnect structure 60. One or more passivation films 64 are on the integrated circuit die 50, such as on portions of the interconnect structure 60 and pads 62. Openings extend through the passivation films 64 to the pads 62. Die connectors 66, such as conductive pillars (for example, formed of a metal such as copper), extend through the openings in the passivation films 64 and are physically and electrically coupled to respective ones of the pads 62. The die connectors 66 may be formed by, for example, plating, or the like. The die connectors 66 electrically couple the respective integrated circuits of the integrated circuit die 50.

Chip probe testing may be performed on the integrated circuit dies 50. Optionally, solder regions (e.g., solder balls or solder bumps) may be disposed on the connectors 66. The solder balls may be used to perform chip probe (CP) testing on the integrated circuit die 50. In some embodiments, the CP testing is performed on the die connectors 66 without the solder regions being present. CP testing may be performed on the integrated circuit die 50 to ascertain whether the integrated circuit die 50 is a known good die (KGD). Thus, only integrated circuit dies 50, which are KGDs, undergo subsequent processing and are packaged, and dies, which fail the CP testing, are not packaged. After testing, the solder regions, if present, may be removed in subsequent processing steps.

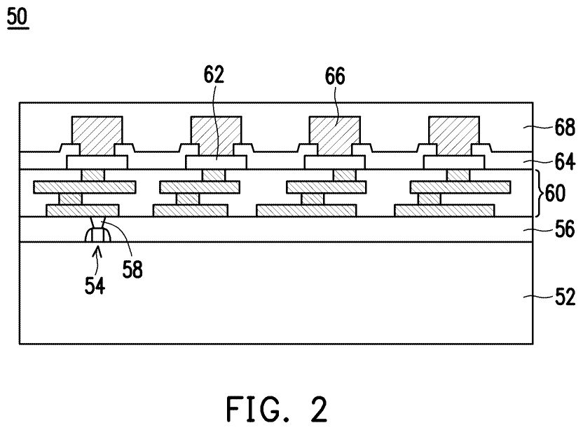

In FIG. 2, a dielectric layer 68 is formed on the active side of the integrated circuit die 50, such as on the passivation films 64 and the die connectors 66. The dielectric layer 68 laterally encapsulates the die connectors 66, and the dielectric layer 68 is laterally coterminous with the integrated circuit die 50. Initially, the dielectric layer 68 may bury the die connectors 66, such that the topmost surface of the dielectric layer 68 is above the topmost surfaces of the die connectors 66. In some embodiments where solder regions are disposed on the die connectors 66, the dielectric layer 68 may bury the solder regions as well. Alternatively, the solder regions may be removed prior to forming the dielectric layer 68.

The dielectric layer 68 may be a polymer such as PBO, polyimide, BCB, or the like; a nitride such as silicon nitride or the like; an oxide such as silicon oxide, PSG, BSG, BPSG, or the like; the like, or a combination thereof. The dielectric layer 68 may be formed, for example, by spin coating, lamination, chemical vapor deposition (CVD), or the like. In some embodiments, the die connectors 66 are exposed through the dielectric layer 68 during formation of the integrated circuit die 50. In some embodiments, the die connectors 66 remain buried and are exposed during a subsequent process for packaging the integrated circuit die 50. Exposing the die connectors 66 may remove any solder regions that may be present on the die connectors 66.

In some embodiments, the integrated circuit die 50 is a stacked device that includes multiple semiconductor substrates 52. For example, the integrated circuit die 50 may be a memory device such as a hybrid memory cube (HMC) module, a high bandwidth memory (HBM) module, or the like that includes multiple memory dies. In such embodiments, the integrated circuit die 50 includes multiple semiconductor substrates 52 interconnected by through-substrate vias (TSVs). Each of the semiconductor substrates 52 may (or may not) have an interconnect structure 60.

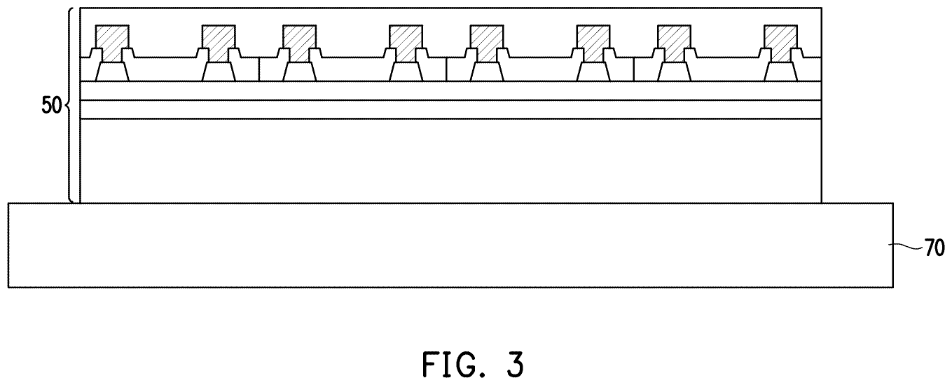

FIGS. 3 through 12B illustrate cross-sectional views of intermediate steps during a process for forming a package component 200, in accordance with some embodiments. Specifically, package component 200 is formed by bonding an integrated circuit die to an integrated circuit die 150. In an embodiment, the package component 200 is a stacked chip package (sometimes referred to as a chiplet package), although it should be appreciated that embodiments may be applied to other three-dimensional integrated circuit (3DIC) packages.

In FIG. 3, the integrated circuit die 50 is attached to a carrier substrate 70. In some embodiments, the integrated circuit die 50 is attached to the carrier substrate 70 with a release layer (not shown). The carrier substrate 70 may be a glass carrier substrate, a ceramic carrier substrate, or the like. The carrier substrate 70 may be a wafer, such that multiple integrated circuit dies 50 can be attached to the carrier substrate 70 simultaneously.

The release layer may be formed of a polymer-based material, which may be removed along with the carrier substrate 70 from the overlying structures that will be formed in subsequent steps. In some embodiments, the release layer is an epoxy-based thermal-release material, which loses its adhesive property when heated, such as a light-to-heat-conversion (LTHC) release coating. In other embodiments, the release layer 304 may be an ultra-violet (UV) glue, which loses its adhesive property when exposed to UV lights. The release layer may be dispensed as a liquid and cured, may be a laminate film laminated onto the carrier substrate 70, or may be the like. The top surface of the release layer may be leveled and may have a high degree of planarity.

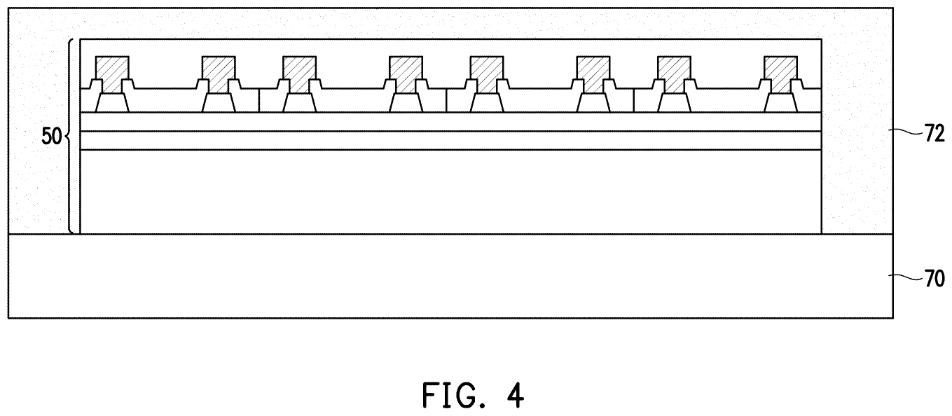

In FIG. 4, an encapsulant 72 is formed on and around integrated circuit die 50. After formation, the encapsulant 72 encapsulates the integrated circuit die 50. The encapsulant 72 may be a molding compound, epoxy, or the like. The encapsulant 72 may be applied by compression molding, transfer molding, or the like, and may be formed over the carrier substrate 70 such that the integrated circuit die 50 is buried or covered. The encapsulant 72 is further formed in gap regions between adjacent integrated circuit dies 50. The encapsulant 72 may be applied in liquid or semi-liquid form and then subsequently cured.

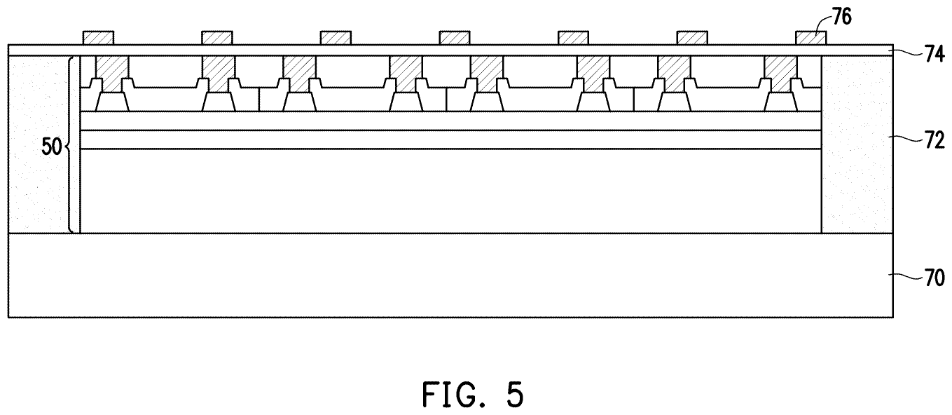

In FIG. 5, a planarization process is performed on the encapsulant 72 to expose the die connectors 66, and a redistribution structure 24 and underbump metallizations (UBMs) 76 are formed. The planarization process may also remove material of the dielectric layer 68, and/or die connectors 66 until the die connectors 66 are exposed. Top surfaces of the die connectors 66, the dielectric layer 68, and encapsulant 72 are substantially coplanar after the planarization process within process variations. The planarization process may be, for example, a chemical-mechanical polish (CMP), a grinding process, or the like. In some embodiments, the planarization may be omitted, for example, if the die connectors 66 are already exposed.

Further in FIG. 5, the redistribution structure 74 is formed over the encapsulant 72 and the integrated circuit die 50. The redistribution structure 74 includes dielectric layers and metallization patterns. The metallization patterns may also be referred to as redistribution layers or redistribution lines. The redistribution structure 74 described below as an example having a single layer of metallization pattern. More dielectric layers and metallization patterns may be formed in the redistribution structure 74. If more dielectric layers and metallization patterns are to be formed, steps and processes discussed below may be repeated.

As an example, a first dielectric layer is deposited on the encapsulant 72 and the die connectors 66. In some embodiments, the dielectric layer is formed of a photo-sensitive material such as PBO, polyimide, BCB, or the like, which may be patterned using a lithography mask. The first dielectric layer may be formed by spin coating, lamination, CVD, the like, or a combination thereof. The first dielectric layer is then patterned. The patterning forms openings exposing portions of the die connectors 66. The patterning may be performed by an acceptable process, such as by exposing and developing the first dielectric layer to light when the dielectric layer is a photo-sensitive material or by etching using, for example, an anisotropic etch.

A metallization pattern is then formed. The metallization pattern includes conductive elements extending along the major surface of the first dielectric layer and extending through the first dielectric layer to physically and electrically couple to the integrated circuit die 50. As an example to form the metallization pattern, a seed layer is formed over the dielectric layer and in the openings extending through the first dielectric layer. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the metallization pattern. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

Next, a second dielectric layer is deposited on the metallization pattern and the first dielectric layer. The second dielectric layer may be formed in a manner similar to the first dielectric layer, and may be formed of a similar material as the first dielectric layer.

Further in FIG. 5, UBMs 76 are formed for external connection to the redistribution structure 74. The UBMs 76 have bump portions on and extending along the major surface of the second dielectric layer, and have via portions extending through the second dielectric layer to physically and electrically couple the metallization pattern. As a result, the UBMs 76 are electrically coupled to the integrated circuit dies 50. The UBMs 76 may be formed of the same material as the metallization pattern. In some embodiments, the UBMs 76 have a different size than the metallization pattern.

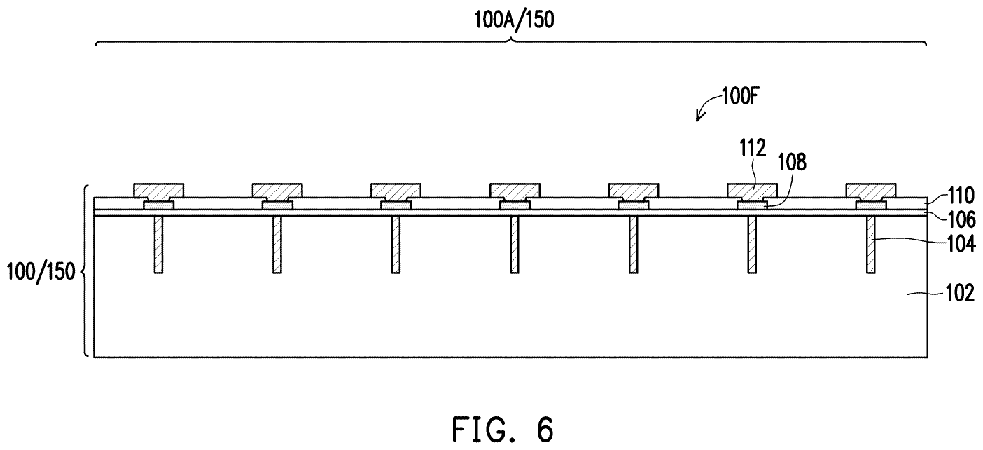

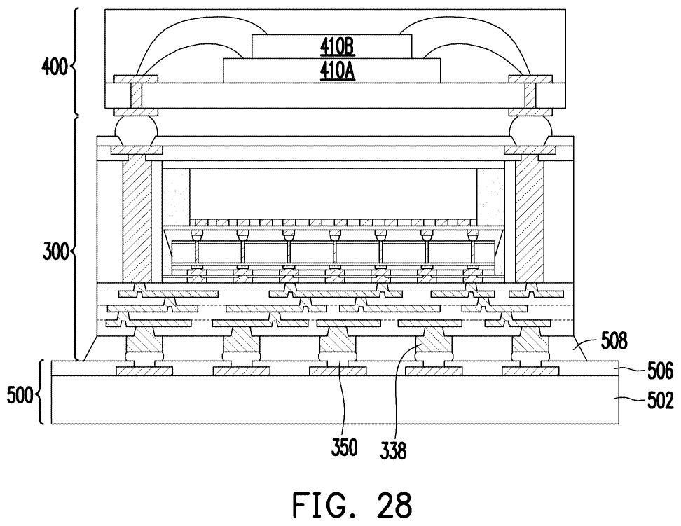

FIGS. 6 through 9 are cross-sectional views of intermediate stages in the forming of an integrated circuit die 150, in accordance with some embodiments. The integrated circuit die 150 will be formed from a wafer 100. The wafer 100 has a die region 100A, which include a device formed therein, such as integrated circuit die 150. Integrated circuit dies 50 will be bonded to the wafer 100 (e.g., with one or more dies 50 in each die region 100A). The die region 100A will be singulated in subsequent processing to form the package component 200, which includes a singulated portion of the wafer 100 (e.g., integrated circuit die 150) and the one or more dies 50. The package component 200 can then be packaged in a fan-out package 300 and mounted to a package substrate 500 (see, e.g., FIG. 28). In an embodiment, the resulting package is integrated fan-out (InFO) package including a system-on-integrated-chip (SoIC) structure, although it should be appreciated that embodiments may be applied to other 3DIC packages.

Processing of one die region 100A of the wafer 100 is illustrated. It should be appreciated that any number of die regions 100A of a wafer 100 can be simultaneously processed and singulated to form multiple integrated circuit dies 150 from the singulated portions of the wafer 100.

In FIG. 6, a wafer 100 is obtained or formed. The wafer 100 comprises devices in the die region 100A, which will be singulated in subsequent processing to be included in the integrated circuit die 150. The devices in the wafer 100 may be integrated circuits dies or the like. In some embodiments, integrated circuit dies 150 are formed in the wafer 100, which include a substrate 102, an interconnect structure 106, conductive vias 104, pads 108, a passivation film 110, and die connectors 112.

The substrate 102 may be a bulk semiconductor substrate, a semiconductor-on-insulator (SOI) substrate, a multi-layered semiconductor substrate, or the like. The substrate 102 may include a semiconductor material, such as silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The substrate 102 may be doped or undoped. In embodiments where interposers are formed in the wafer 100, the substrate 102 generally does not include active devices therein, although the interposers may include passive devices formed in and/or on a front surface (e.g., the surface facing upward in FIG. 6) of the substrate 102. In embodiments where integrated circuits devices are formed in the wafer 100, active devices such as transistors, capacitors, resistors, diodes, and the like, may be formed in and/or on the front surface of the substrate 102.

The interconnect structure 106 is over the front surface of the substrate 102, and is used to electrically connect the devices (if any) of the substrate 102. The interconnect structure 106 may include one or more dielectric layer(s) and respective metallization layer(s) in the dielectric layer(s). Acceptable dielectric materials for the dielectric layers include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The metallization layer(s) may include conductive vias and/or conductive lines to interconnect any devices together and/or to an external device. The metallization layer(s) may be formed of a conductive material, such as a metal, such as copper, cobalt, aluminum, gold, combinations thereof, or the like. The interconnect structure 106 may be formed by a damascene process, such as a single damascene process, a dual damascene process, or the like.

The conductive vias 104 extend into the interconnect structure 106 and/or the substrate 102. The conductive vias 104 are electrically connected to metallization layer(s) of the interconnect structure 106. The conductive vias 104 are also sometimes referred to as TSVs. As an example to form the conductive vias 104, recesses can be formed in the interconnect structure 106 and/or the substrate 102 by, for example, etching, milling, laser techniques, a combination thereof, and/or the like. A thin dielectric material may be formed in the recesses, such as by using an oxidation technique. A thin barrier layer may be conformally deposited in the openings, such as by CVD, atomic layer deposition (ALD), physical vapor deposition (PVD), thermal oxidation, a combination thereof, and/or the like. The barrier layer may be formed of an oxide, a nitride, a carbide, combinations thereof, or the like. A conductive material may be deposited over the barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from a surface of the interconnect structure 106 or the substrate 102 by, for example, a CMP. Remaining portions of the barrier layer and conductive material form the conductive vias 104.

The pads 108, passivation film 110, and die connectors 112 are formed over the interconnect structure 106. The die connectors 112 may also be referred to as conductive vias 112. The pads 108, passivation film 110, and die connectors 112 may be formed by similar processes and of similar materials as the pads 62, passivation film 64, and die connectors 66 as described above. In some embodiments, the die connectors 112 extend through the passivation film 110 to physically contact the pads 108 and extend along a top surface of the passivation film 110.

Chip probe testing may be performed on the die regions 100A of the wafer 100. Optionally, solder regions (e.g., solder balls or solder bumps) may be disposed on the connectors 112. The solder balls may be used to perform chip probe (CP) testing on the die regions 100A. In some embodiments, the CP testing is performed on the die connectors 112 without the solder regions being present. CP testing may be performed on the die regions 100A to ascertain whether the die regions 100A (integrated circuit die 150 after singulation) is a known good die (KGD). Thus, only integrated circuit dies 150, which are KGDs, undergo subsequent processing and are packaged, and dies, which fail the CP testing, are not packaged. After testing, the solder regions, if present, may be removed in subsequent processing steps.

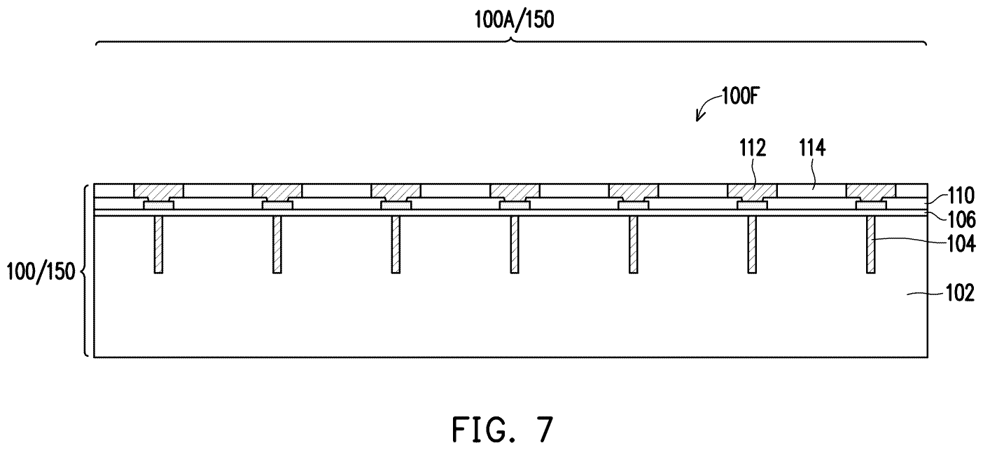

In FIG. 7, a dielectric layer 114 is formed on the front side 100F of the wafer 100, such as on the passivation films 110 and the die connectors 112. The dielectric layer 114 laterally encapsulates the die connectors 112, and the dielectric layer 114 is laterally coterminous with the wafer 100. Initially, the dielectric layer 114 may bury the die connectors 112, such that the topmost surface of the dielectric layer 114 is above the topmost surfaces of the die connectors 112. In some embodiments where solder regions are disposed on the die connectors 112, the dielectric layer 114 may bury the solder regions as well. Alternatively, the solder regions may be removed prior to forming the dielectric layer 114.

The dielectric layer 114 may be a polymer such as PBO, polyimide, BCB, or the like; a nitride such as silicon nitride or the like; an oxide such as silicon oxide, PSG, BSG, BPSG, or the like; the like, or a combination thereof. The dielectric layer 114 may be formed, for example, by spin coating, lamination, CVD, or the like. In some embodiments, the die connectors 112 are exposed through the dielectric layer 114 during formation of the wafer 100. In some embodiments, the die connectors 112 remain buried and are exposed during a subsequent process. Exposing the die connectors 112 may remove any solder regions that may be present on the die connectors 112.

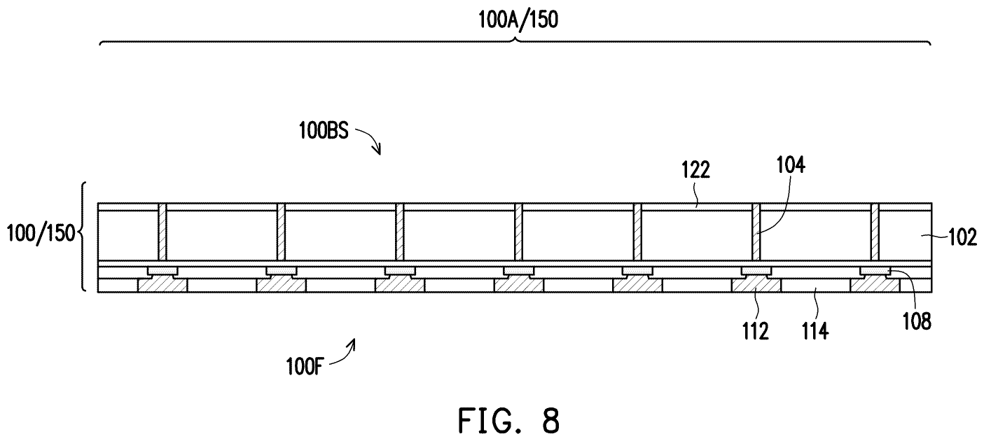

In FIG. 8, the wafer 100 is flipped over and the substrate 102 is thinned to expose the conductive vias 104. Exposure of the conductive vias 104 may be accomplished by a thinning process, such as a grinding process, a chemical-mechanical polish (CMP), an etch-back, combinations thereof, or the like. In the illustrated embodiment, a recessing process is performed to recess the back surface of the substrate 102 such that the conductive vias 104 protrude at the back side 100BS of the wafer 100. The recessing process may be, e.g., a suitable etch-back process, chemical-mechanical polish (CMP), or the like. In some embodiments, the thinning process for exposing the conductive vias 104 includes a CMP, and the conductive vias 104 protrude at the back side 100BS of the wafer 100 as a result of dishing that occurs during the CMP. An insulating layer 122 is optionally formed on the back surface of the substrate 102, surrounding the protruding portions of the conductive vias 104. In some embodiments, the insulating layer 122 is formed of a silicon-containing insulator, such as, silicon nitride, silicon oxide, silicon oxynitride, or the like, and may be formed by a suitable deposition method such as spin coating, CVD, plasma-enhanced CVD (PECVD), high density plasma CVD (HDP-CVD), or the like. Initially, the insulating layer 122 may bury the conductive vias 104. A removal process can be applied to the various layers to remove excess materials over the conductive vias 104. The removal process may be a planarization process such as a chemical mechanical polish (CMP), an etch-back, combinations thereof, or the like. After planarization, the exposed surfaces of the conductive vias 104 and the insulating layer 122 are coplanar (within process variations) and are exposed at the back side 100BS of the wafer 100. In another embodiment, the insulating layer 122 is omitted, and the exposed surfaces of the substrate 102 and the conductive vias 104 are coplanar (within process variations).

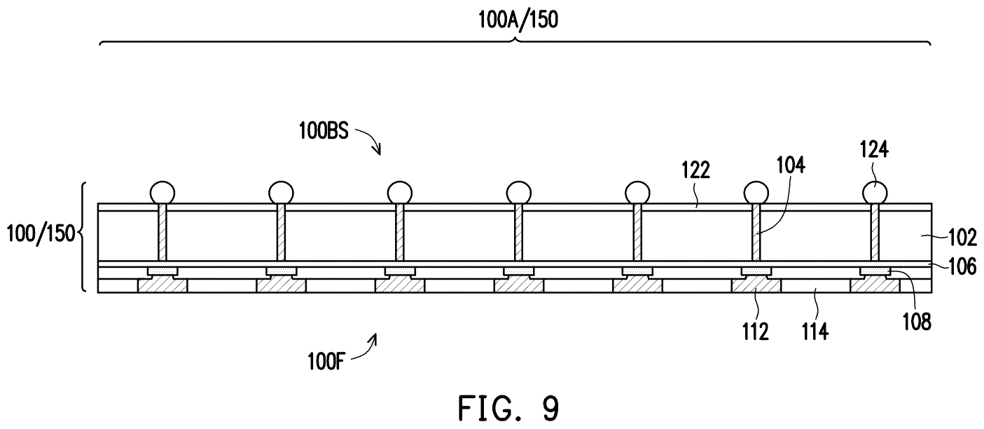

In FIG. 9, UBMs (not separately illustrated) and conductive connectors 124 are formed on the exposed surfaces of the conductive vias 104 and the insulating layer 122 (or the substrate 102, when the insulating layer 122 is omitted). As an example to form the UBMs, a seed layer (not separately illustrated) is formed over the exposed surfaces of the conductive vias 104 and the insulating layer 122 (if present) or the substrate 102. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the UBMs. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the UBMs.

Further, conductive connectors 124 are formed on the UBMs. The conductive connectors 124 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 124 may be formed of a conductive material that is reflowable, such as solder, copper, aluminum, gold, nickel, silver, palladium, tin, the like, or a combination thereof. In some embodiments, the conductive connectors 124 are formed by initially forming a layer of solder through evaporation, electroplating, printing, solder transfer, ball placement, or the like. Once a layer of solder has been formed on the structure, a reflow may be performed in order to shape the material into desired bump shapes. In another embodiment, the conductive connectors 124 comprise metal pillars (such as copper pillars) formed by sputtering, printing, electro plating, electroless plating, CVD, or the like. The metal pillars may be solder-free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

Further, a singulation process is performed by cutting along scribe line regions, e.g., around the die region 100A. The singulation process may include sawing, dicing, or the like. For example, the singulation process can include sawing the insulating layer 122, the substrate 102, the interconnect structure 106, the passivation film 110, and the dielectric layer 114. The singulation process singulates the die region 100A from adjacent die regions. The resulting, singulated integrated circuit die 150 is from the die region 100A. The singulation process forms dies 150 from the singulated portions of the wafer 100.

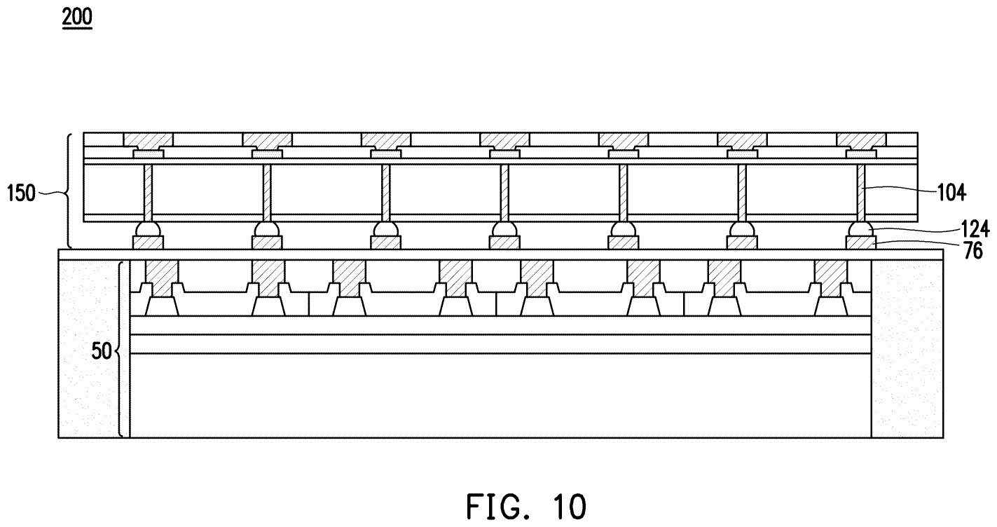

FIGS. 10 through 12B are cross-sectional views of intermediate stages in the forming of the package component 200, in accordance with some embodiments. In FIG. 10, the integrated circuit die 150 is then flipped and attached to a partially packaged integrated circuit die of FIG. 5 using the conductive connectors 124. The conductive connectors 124 are reflowed to attach the UBMs 76 to the UBMs of the integrated circuit die 150. The conductive connectors 124 connect the integrated circuit die 150, including metallization layers of the interconnect structure 106, to the integrated circuit die 50, including metallization layers in the interconnect structure 60. Thus, the integrated circuit die 50 is electrically connected to the integrated circuit die 150. In some embodiments, passive devices (e.g., surface mount devices (SMDs), not separately illustrated) may be attached to the integrated circuit dies 50 and/or 150 (e.g., bonded to the UBMs) prior to bonding the dies together. In such embodiments, the passive devices may be bonded to a same surface of the integrated circuit dies 50 and/or 150 as the conductive connectors 124.

Although a single set of integrated circuit dies 50 and 150 are shown being bonded together, many integrated circuit dies 150 may be bonded simultaneously to many integrated circuit dies 50 in a reconstituted wafer form.

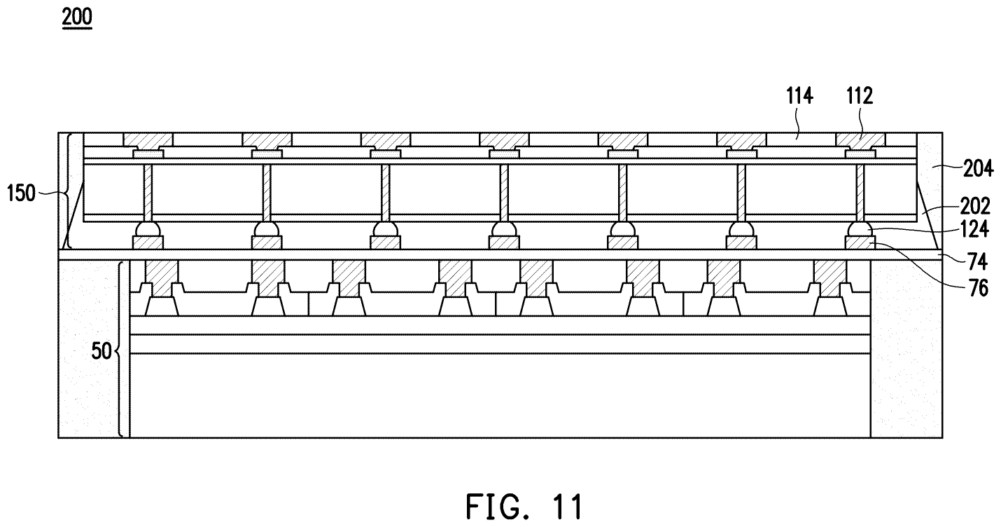

In FIG. 11, an underfill 202 is formed between the integrated circuit dies 50 and 150, surrounding the conductive connectors 124 and the UBMs. The underfill 202 may be formed by a capillary flow process after the integrated circuit die 150 is attached or may be formed by a suitable deposition method before the integrated circuit die 150 is attached. The underfill 202 may be a continuous material extending from the integrated circuit die 50 (e.g., the redistribution structure 74) to the integrated circuit die 150 (e.g., the insulating layer 122).

After the underfill 202 is formed, an encapsulant 204 is formed on and around integrated circuit die 150 and the underfill 202. After formation, the encapsulant 204 encapsulates the integrated circuit die 150 and the underfill 202. The encapsulant 204 may be a molding compound, epoxy, or the like. The encapsulant 204 may be applied by compression molding, transfer molding, or the like, and may be formed over the integrated circuit die 50 such that the integrated circuit die 150 is buried or covered. The encapsulant 204 is further formed in gap regions between adjacent integrated circuit dies 150. The encapsulant 204 may be applied in liquid or semi-liquid form and then subsequently cured. In some embodiments, the encapsulant 204 and the encapsulant 72 are formed of different materials. In some embodiments, the encapsulant 204 and the encapsulant 72 are formed of the same materials.

Further in FIG. 11, a planarization process is performed on the encapsulant 204 to expose the die connectors 112 and the dielectric layer 114. The planarization process may also remove material of the dielectric layer 114 and/or die connectors 112 until the die connectors 112 are exposed. Top surfaces of the die connectors 112, the dielectric layer 114, and encapsulant 204 are substantially coplanar after the planarization process within process variations. The planarization process may be, for example, a CMP, a grinding process, or the like. In some embodiments, the planarization may be omitted, for example, if the die connectors 112 are already exposed.

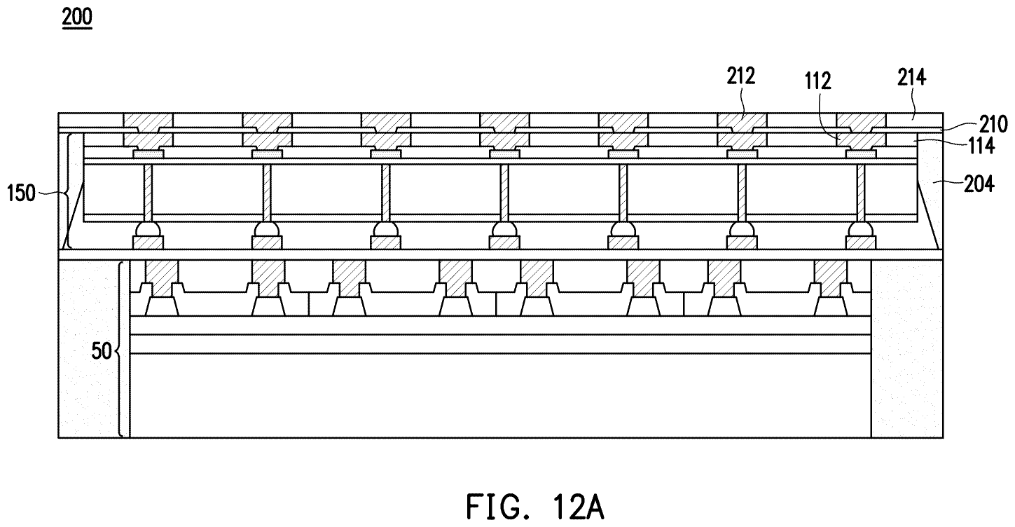

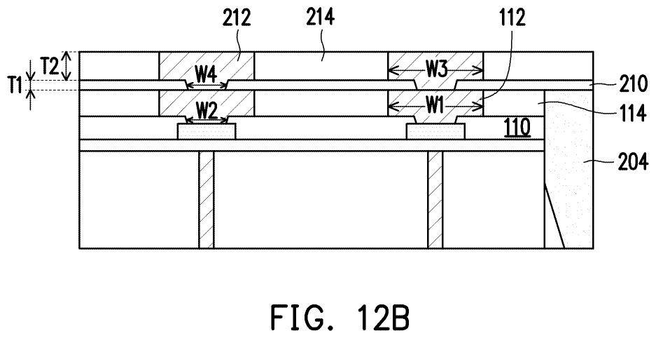

In FIGS. 12A and 12B, dielectric layers 210 and 214 and connectors 212 are formed over the connectors 112, the dielectric layer 114, and the encapsulant 204. FIG. 12B illustrates a detailed view of a portion of FIG. 12A including connectors 212 and dielectric layers 210 and 214. The dielectric layers 210 and 214 and the connectors 212 may be formed by similar processes and materials as the dielectric layer 114 and the connectors 112 described above. In some embodiments, the dielectric layers 114, 210, and 214 are formed of different materials. In some embodiments, the dielectric layers 114, 210, and 214 are formed of the same materials. For example, in an embodiment, the dielectric layer 114 may be a polyimide, and the dielectric layers 210 and 214 may be other types of polymers, such as PBO, BCB, or the like.

The dielectric layer 210 may be formed to have a thickness T1 and the dielectric layer 214 may be formed to have a thickness T2. In some embodiments, a ratio of T1/T2 is in a range from 0.53 to 2.9.

The connectors 112 may be formed to have a width W1 in the dielectric layer 114 and a width W2 in the passivation film 110. In some embodiments, the width W2 is larger than the width W1, and, in other embodiments, the width W2 is smaller than the width W1. The connectors 212 may be formed to have a width W3 in the dielectric layer 214 and a width W4 in the dielectric layer 210. In some embodiments, the width W4 is larger than the width W3, and, in other embodiments, the width W4 is smaller than the width W3. In some embodiments, a ratio of W3/W1 is in a range from 0.63 to 1.93. In some embodiments, a ratio of W4/W2 is in a range from 0.8 to 2.

As shown in FIGS. 12A and 12B, the dielectric layers 210 and 214 overlap the encapsulant 204 such that the dielectric layer 210 is over and contacting a top surface of the encapsulant 204.

Further, a singulation process is performed by cutting along scribe line regions. The singulation process may include sawing, dicing, or the like. For example, the singulation process can include sawing the dielectric layers 214 and 210, the encapsulant 204, the redistribution structure 74, and the encapsulant 72. The singulation process forms package components 200. After singulation, the sidewalls of the dielectric layers 214 and 210, the encapsulant 204, the redistribution structure 74, and the encapsulant 72 are coterminous within process variations.

By having the stacked connector structure 112/212 and multiple dielectric layers 114/210/214 allows for the ability to test the dies 50 and 150 while also allowing for a lower chip package interaction (CPI) risk. For example, the stacked connectors 112/212 and multiple dielectric layers allow for each of the dies of a chiplet structure 200 to be tested and be known good dies (KGDs) while providing protection for the dies during and after the testing.

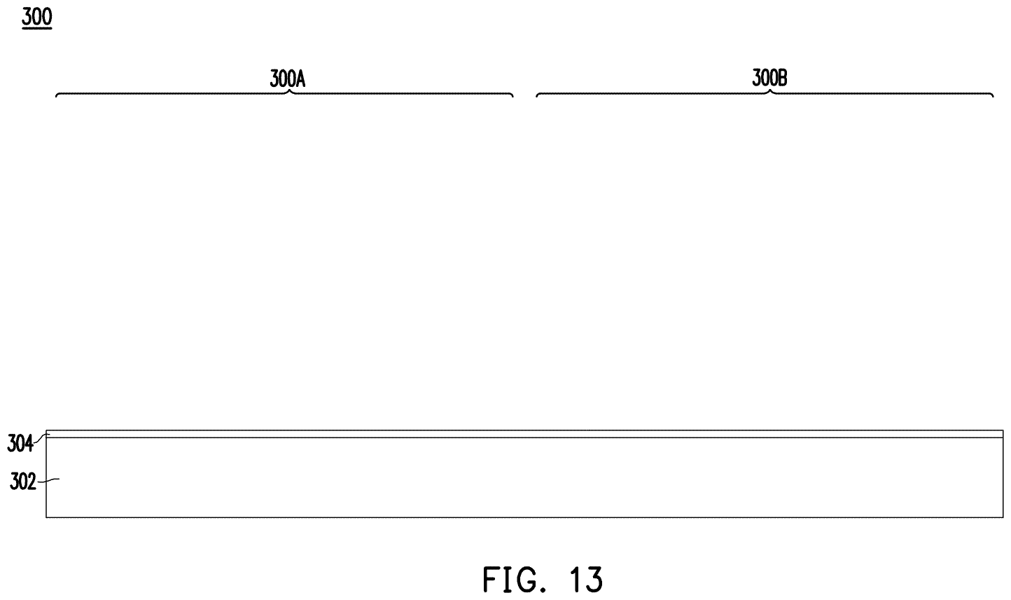

FIGS. 13 through 26 illustrate cross-sectional views of intermediate steps during a process for forming a package component 300, in accordance with some embodiments. A first package region 300A and a second package region 300B are illustrated, and one or more of the package components 200 are packaged to form an integrated circuit package in each of the package regions 300A and 300B. The integrated circuit packages may also be referred to as integrated fan-out (InFO) packages.

In FIG. 13, a carrier substrate 302 is provided, and a release layer 304 is formed on the carrier substrate 302. The carrier substrate 302 may be a glass carrier substrate, a ceramic carrier substrate, or the like. The carrier substrate 302 may be a wafer, such that multiple packages can be formed on the carrier substrate 302 simultaneously.

The release layer 304 may be formed of a polymer-based material, which may be removed along with the carrier substrate 302 from the overlying structures that will be formed in subsequent steps. In some embodiments, the release layer 304 is an epoxy-based thermal-release material, which loses its adhesive property when heated, such as a light-to-heat-conversion (LTHC) release coating. In other embodiments, the release layer 304 may be an ultra-violet (UV) glue, which loses its adhesive property when exposed to UV lights. The release layer 304 may be dispensed as a liquid and cured, may be a laminate film laminated onto the carrier substrate 302, or may be the like. The top surface of the release layer 304 may be leveled and may have a high degree of planarity.

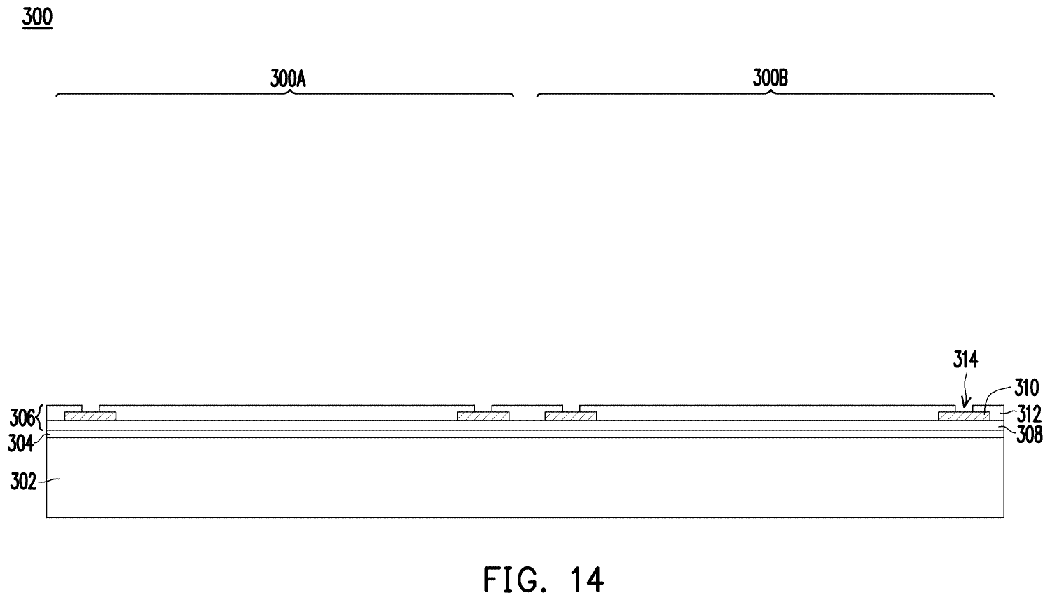

In FIG. 14, a back-side redistribution structure 306 may be formed on the release layer 304. In the embodiment shown, the back-side redistribution structure 306 includes a dielectric layer 308, a metallization pattern 310 (sometimes referred to as redistribution layers or redistribution lines), and a dielectric layer 312. The back-side redistribution structure 306 is optional. In some embodiments, a dielectric layer without metallization patterns is formed on the release layer 304 in lieu of the back-side redistribution structure 306.

The dielectric layer 308 may be formed on the release layer 304. The bottom surface of the dielectric layer 308 may be in contact with the top surface of the release layer 304. In some embodiments, the dielectric layer 308 is formed of a polymer, such as polybenzoxazole (PBO), polyimide, benzocyclobutene (BCB), or the like. In other embodiments, the dielectric layer 308 is formed of a nitride such as silicon nitride; an oxide such as silicon oxide, phosphosilicate glass (PSG), borosilicate glass (BSG), boron-doped phosphosilicate glass (BPSG), or the like; or the like. The dielectric layer 308 may be formed by any acceptable deposition process, such as spin coating, CVD, laminating, the like, or a combination thereof.

The metallization pattern 310 may be formed on the dielectric layer 308. As an example to form metallization pattern 310, a seed layer is formed over the dielectric layer 308. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist (not shown) is then formed and patterned on the seed layer. The photoresist may be formed by spin coating or the like and may be exposed to light for patterning. The pattern of the photoresist corresponds to the metallization pattern 310. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the metallization pattern 310.

The dielectric layer 312 may be formed on the metallization pattern 310 and the dielectric layer 308. In some embodiments, the dielectric layer 312 is formed of a polymer, which may be a photo-sensitive material such as PBO, polyimide, BCB, or the like, that may be patterned using a lithography mask. In other embodiments, the dielectric layer 312 is formed of a nitride such as silicon nitride; an oxide such as silicon oxide, PSG, BSG, BPSG; or the like. The dielectric layer 312 may be formed by spin coating, lamination, CVD, the like, or a combination thereof. The dielectric layer 312 is then patterned to form openings 314 exposing portions of the metallization pattern 310. The patterning may be performed by an acceptable process, such as by exposing the dielectric layer 312 to light when the dielectric layer 312 is a photo-sensitive material or by etching using, for example, an anisotropic etch. If the dielectric layer 312 is a photo-sensitive material, the dielectric layer 312 can be developed after the exposure.

FIG. 14 illustrates a redistribution structure 306 having a single metallization pattern 310 for illustrative purposes. In some embodiments, the back-side redistribution structure 306 may include any number of dielectric layers and metallization patterns. If more dielectric layers and metallization patterns are to be formed, steps and processes discussed above may be repeated. The metallization patterns may include one or more conductive elements. The conductive elements may be formed during the formation of the metallization pattern by forming the seed layer and conductive material of the metallization pattern over a surface of the underlying dielectric layer and in the opening of the underlying dielectric layer, thereby interconnecting and electrically coupling various conductive lines.

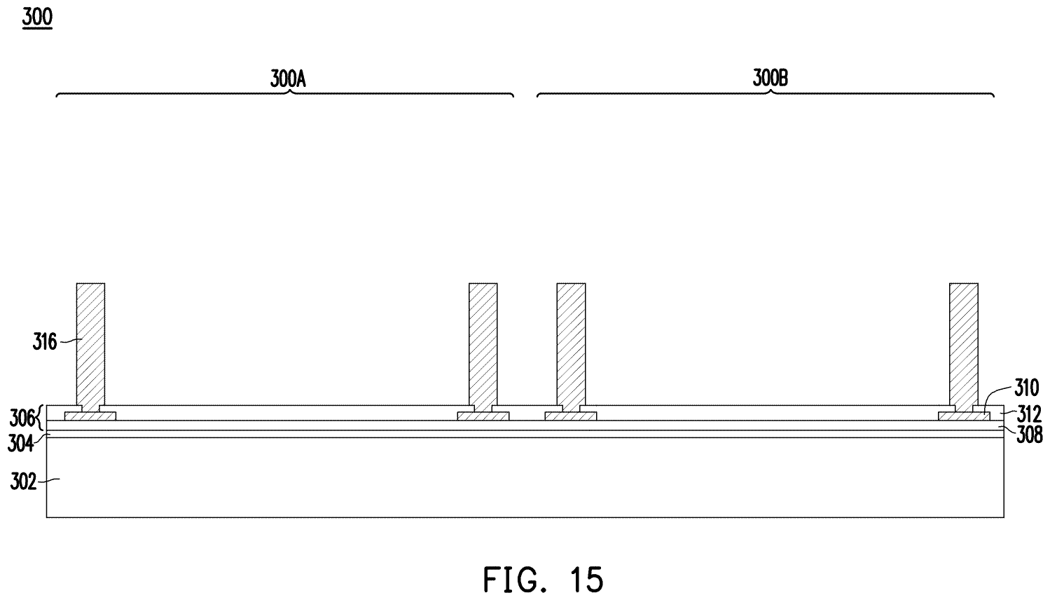

In FIG. 15, through vias 316 are formed in the openings 314 and extending away from the topmost dielectric layer of the back-side redistribution structure 306 (e.g., the dielectric layer 312). As an example to form the through vias 316, a seed layer (not shown) is formed over the back-side redistribution structure 306, e.g., on the dielectric layer 312 and portions of the metallization pattern 310 exposed by the openings 314. In some embodiments, the seed layer is a metal layer, which may be a single layer or a composite layer comprising a plurality of sub-layers formed of different materials. In a particular embodiment, the seed layer comprises a titanium layer and a copper layer over the titanium layer. The seed layer may be formed using, for example, PVD or the like. A photoresist is formed and patterned on the seed layer.

The photoresist may be formed by spin coating or the like and may be exposed to light for patterning. The pattern of the photoresist corresponds to conductive vias. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the through vias 316.

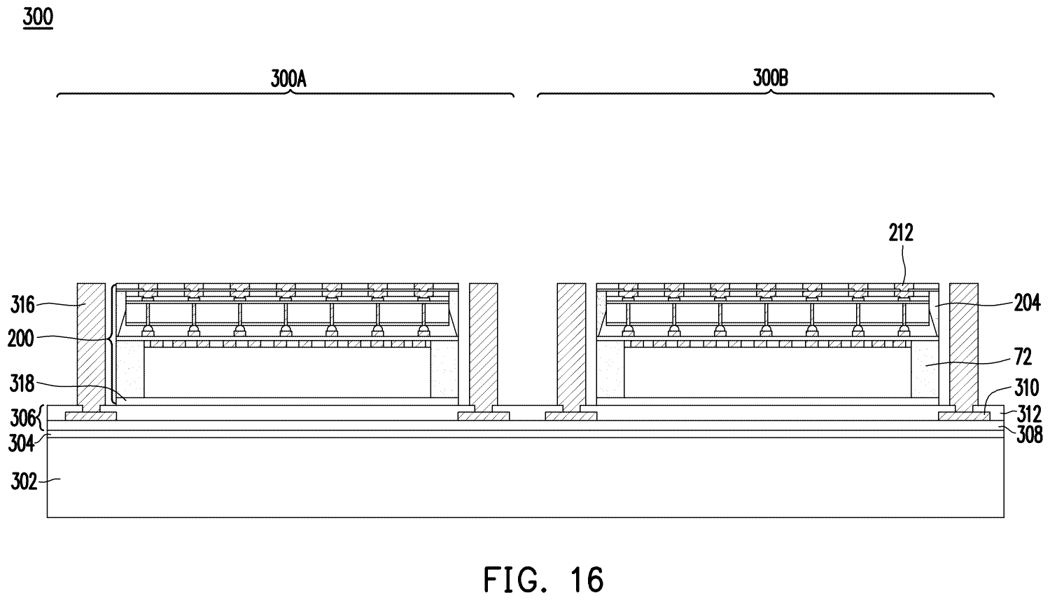

In FIG. 16, package components 200 are adhered to the dielectric layer 312 by an adhesive 318. A desired type and quantity of package components 200 are adhered in each of the package regions 300A and 300B. In the embodiment shown, a single package components 200 is adhered in each of the first package region 300A and the second package region 300B. In some embodiments, multiple package components 200 may be adhered adjacent each other in each of the package regions 300A and 300B. In the case of multiple package components 200, the package components 200 may have different sizes (e.g., different heights and/or surface areas), or may have the same size (e.g., same heights and/or surface areas). The space available for the through vias 316 in the first package region 300A and the second package region 300B may be limited, particularly when the package components 200 include devices with a large footprint, such as SoCs. Use of the back-side redistribution structure 306 allows for an improved interconnect arrangement when the first package region 300A and the second package region 300B have limited space available for the through vias 316.

The adhesive 318 is on back-sides of the package components 200 and adheres the package components 200 to the back-side redistribution structure 306, such as to the dielectric layer 312. The adhesive 318 may be any suitable adhesive, epoxy, die attach film (DAF), or the like. The adhesive 318 may be applied to back-sides of the package components 200, may be applied over the surface of the carrier substrate 302 if no back-side redistribution structure 306 is utilized, or may be applied to an upper surface of the back-side redistribution structure 306 if applicable.

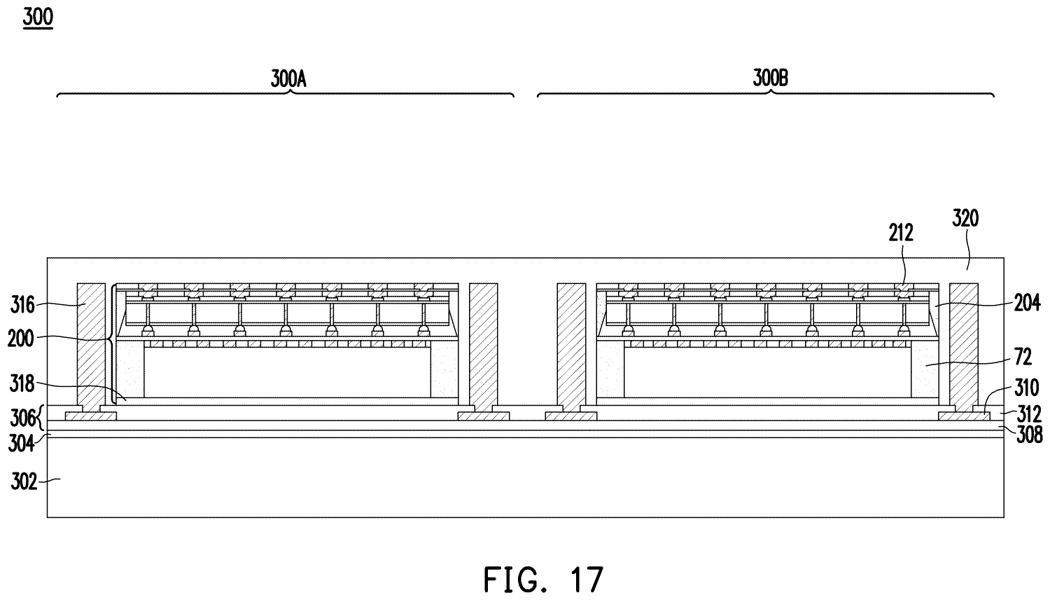

In FIG. 17, an encapsulant 320 is formed on and around the various components. After formation, the encapsulant 320 encapsulates the through vias 316 and package components 200. The encapsulant 320 may be a molding compound, epoxy, or the like. The encapsulant 320 may be applied by compression molding, transfer molding, or the like, and may be formed over the carrier substrate 302 such that the through vias 316 and/or the components 200 are buried or covered. The encapsulant 320 is further formed in gap regions between the package components 200 and the through vias 316. The encapsulant 320 physically contacts the encapsulants 204 and 72 of the package components 200. The encapsulant 320 may be applied in liquid or semi-liquid form and then subsequently cured. In some embodiments, the encapsulants 320, 204, and 72 are formed of different materials. In some embodiments, the encapsulants 320, 204, and 72 are formed of the same materials.

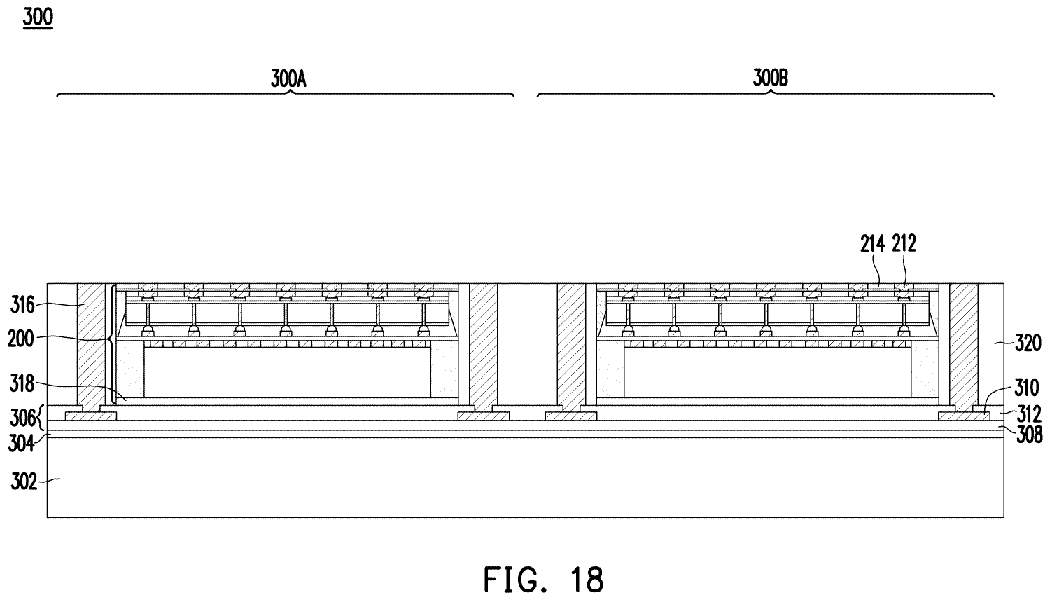

In FIG. 18, a planarization process is performed on the encapsulant 320 to expose the through vias 316 and the connectors 212. The planarization process may also remove material of the through vias 316, dielectric layer 214, and/or connectors 212 until the connectors 212 and through vias 316 are exposed. Top surfaces of the through vias 316, connectors 212, dielectric layer 214, and encapsulant 320 are substantially coplanar after the planarization process within process variations. The planarization process may be, for example, a CMP, a grinding process, or the like. In some embodiments, the planarization may be omitted, for example, if the through vias 316 and/or connectors 212 are already exposed.

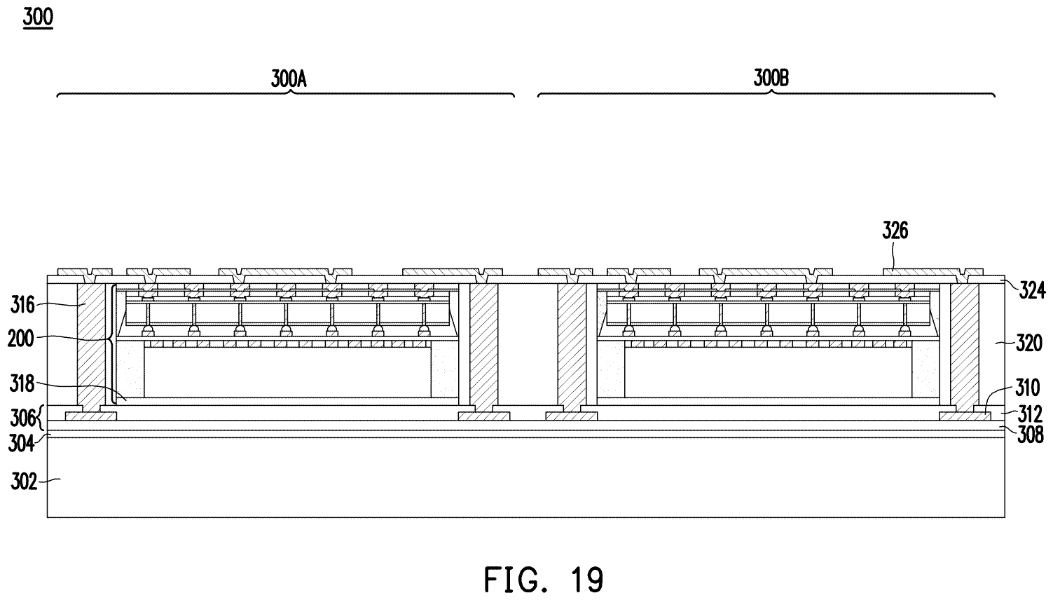

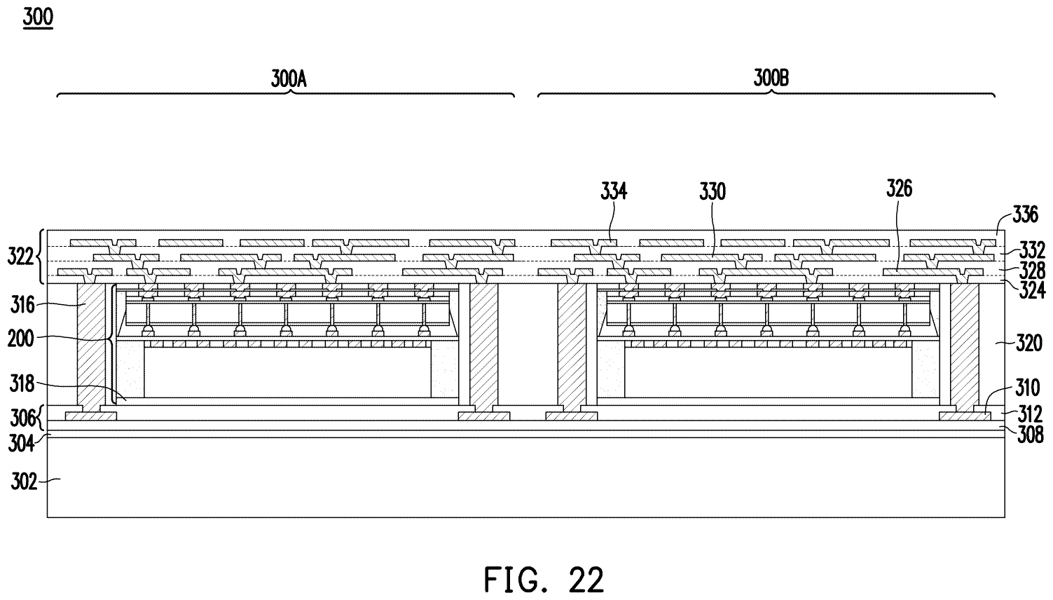

In FIGS. 19 through 22, a front-side redistribution structure 322 (see FIG. 22) is formed over the encapsulant 320, through vias 316, and package components 200. The front-side redistribution structure 322 includes dielectric layers 324, 328, 332, and 336; and metallization patterns 326, 330, and 334. The metallization patterns may also be referred to as redistribution layers or redistribution lines. The front-side redistribution structure 322 is shown as an example having three layers of metallization patterns. More or fewer dielectric layers and metallization patterns may be formed in the front-side redistribution structure 322. If fewer dielectric layers and metallization patterns are to be formed, steps and process discussed below may be omitted. If more dielectric layers and metallization patterns are to be formed, steps and processes discussed below may be repeated.

In FIG. 19, the dielectric layer 324 is deposited on the encapsulant 320, through vias 316, and connectors 212. In some embodiments, the dielectric layer 324 is formed of a photo-sensitive material such as PBO, polyimide, BCB, or the like, which may be patterned using a lithography mask. The dielectric layer 324 may be formed by spin coating, lamination, CVD, the like, or a combination thereof. The dielectric layer 324 is then patterned. The patterning forms openings exposing portions of the through vias 316 and the connectors 212. The patterning may be performed by an acceptable process, such as by exposing and developing the dielectric layer 324 to light when the dielectric layer 324 is a photo-sensitive material or by etching using, for example, an anisotropic etch.

The metallization pattern 326 is then formed. The metallization pattern 326 includes conductive elements extending along the major surface of the dielectric layer 324 and extending through the dielectric layer 324 to physically and electrically couple to the through vias 316 and the package components 200. As an example to form the metallization pattern 326, a seed layer is formed over the dielectric layer 324 and in the openings extending through the dielectric layer 324. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern 326. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the metallization pattern 326. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

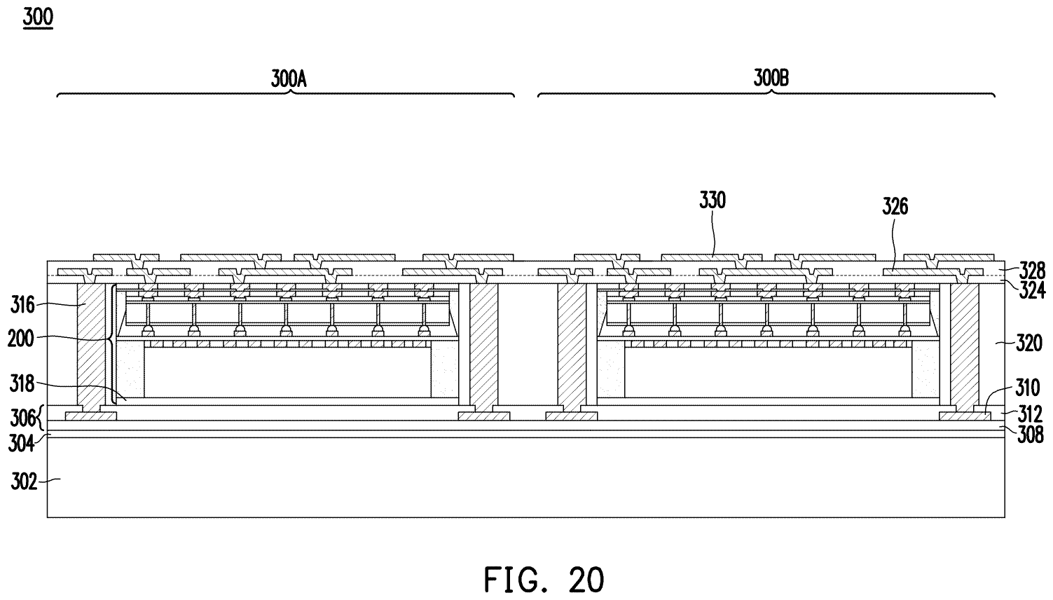

In FIG. 20, the dielectric layer 328 is deposited on the metallization pattern 326 and the dielectric layer 324. The dielectric layer 328 may be formed in a manner similar to the dielectric layer 324, and may be formed of a similar material as the dielectric layer 324.

The metallization pattern 330 is then formed. The metallization pattern 330 includes portions on and extending along the major surface of the dielectric layer 328. The metallization pattern 330 further includes portions extending through the dielectric layer 328 to physically and electrically couple the metallization pattern 326. The metallization pattern 330 may be formed in a similar manner and of a similar material as the metallization pattern 326. In some embodiments, the metallization pattern 330 has a different size than the metallization pattern 326. For example, the conductive lines and/or vias of the metallization pattern 330 may be wider or thicker than the conductive lines and/or vias of the metallization pattern 326. Further, the metallization pattern 330 may be formed to a greater pitch than the metallization pattern 326.

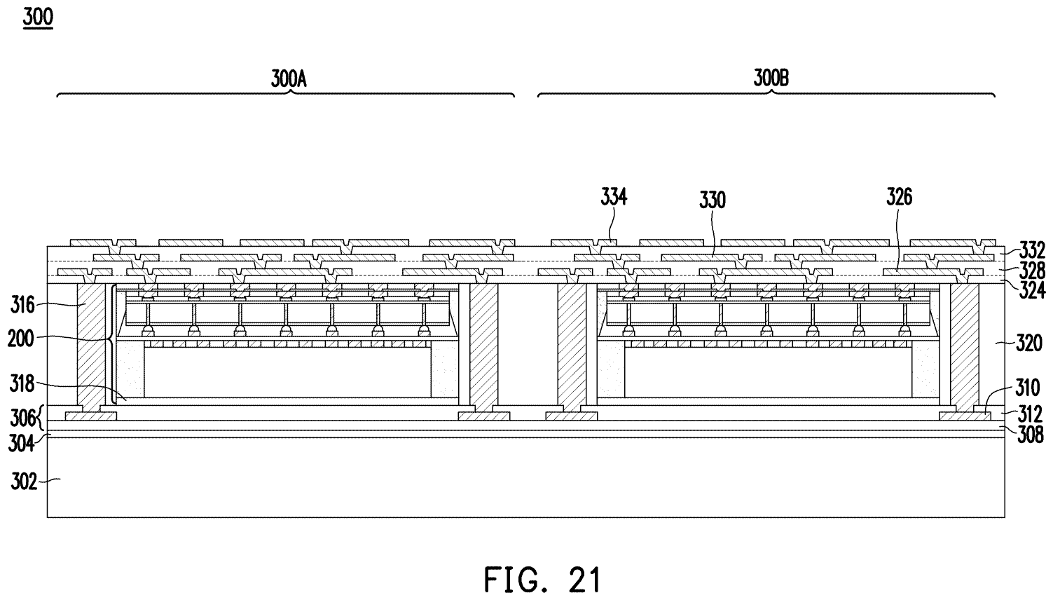

In FIG. 21, the dielectric layer 332 is deposited on the metallization pattern 330 and the dielectric layer 328. The dielectric layer 332 may be formed in a manner similar to the dielectric layer 324, and may be formed of a similar material as the dielectric layer 324.

The metallization pattern 334 is then formed. The metallization pattern 334 includes portions on and extending along the major surface of the dielectric layer 332. The metallization pattern 334 further includes portions extending through the dielectric layer 332 to physically and electrically couple the metallization pattern 330. The metallization pattern 334 may be formed in a similar manner and of a similar material as the metallization pattern 326. The metallization pattern 334 is the topmost metallization pattern of the front-side redistribution structure 322. As such, all of the intermediate metallization patterns of the front-side redistribution structure 322 (e.g., the metallization patterns 326 and 330) are disposed between the metallization pattern 334 and the package components 200. In some embodiments, the metallization pattern 334 has a different size than the metallization patterns 326 and 330. For example, the conductive lines and/or vias of the metallization pattern 334 may be wider or thicker than the conductive lines and/or vias of the metallization patterns 326 and 330. Further, the metallization pattern 334 may be formed to a greater pitch than the metallization pattern 330.

In FIG. 22, the dielectric layer 336 is deposited on the metallization pattern 334 and the dielectric layer 332. The dielectric layer 336 may be formed in a manner similar to the dielectric layer 324, and may be formed of the same material as the dielectric layer 324. The dielectric layer 336 is the topmost dielectric layer of the front-side redistribution structure 322. As such, all of the metallization patterns of the front-side redistribution structure 322 (e.g., the metallization patterns 326, 330, and 334) are disposed between the dielectric layer 336 and the package components 200. Further, all of the intermediate dielectric layers of the front-side redistribution structure 322 (e.g., the dielectric layers 324, 328, 332) are disposed between the dielectric layer 336 and the package components 200.

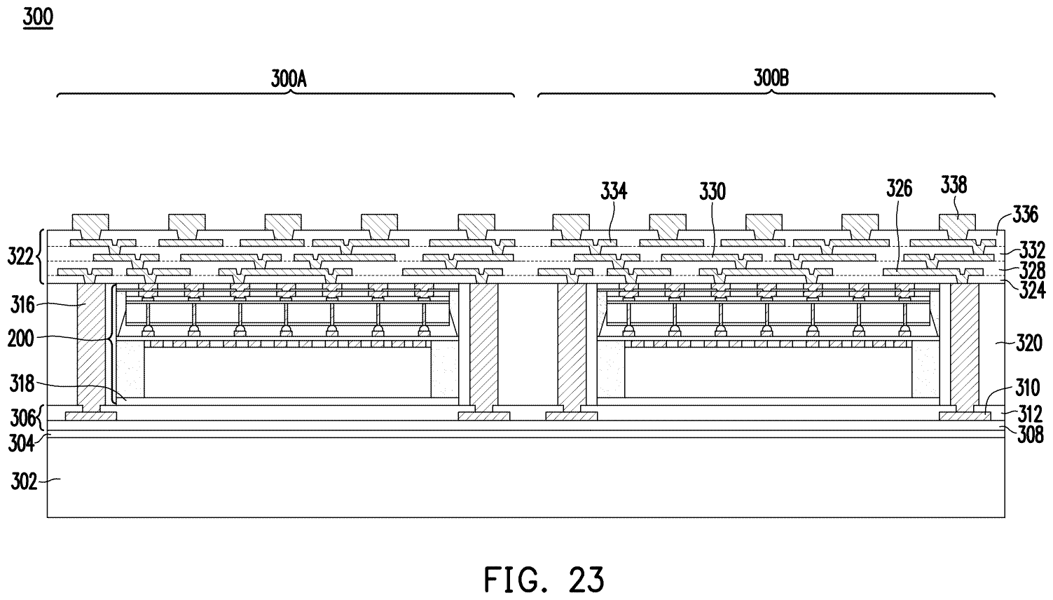

In FIG. 23, UBMs 338 are formed for external connection to the front-side redistribution structure 322. The UBMs 338 have bump portions on and extending along the major surface of the dielectric layer 336, and have via portions extending through the dielectric layer 336 to physically and electrically couple the metallization pattern 334. As a result, the UBMs 338 are electrically coupled to the through vias 316 and the package components 200. The UBMs 338 may be formed of the same material as the metallization pattern 326. In some embodiments, the UBMs 338 have a different size than the metallization patterns 326, 330, and 334.

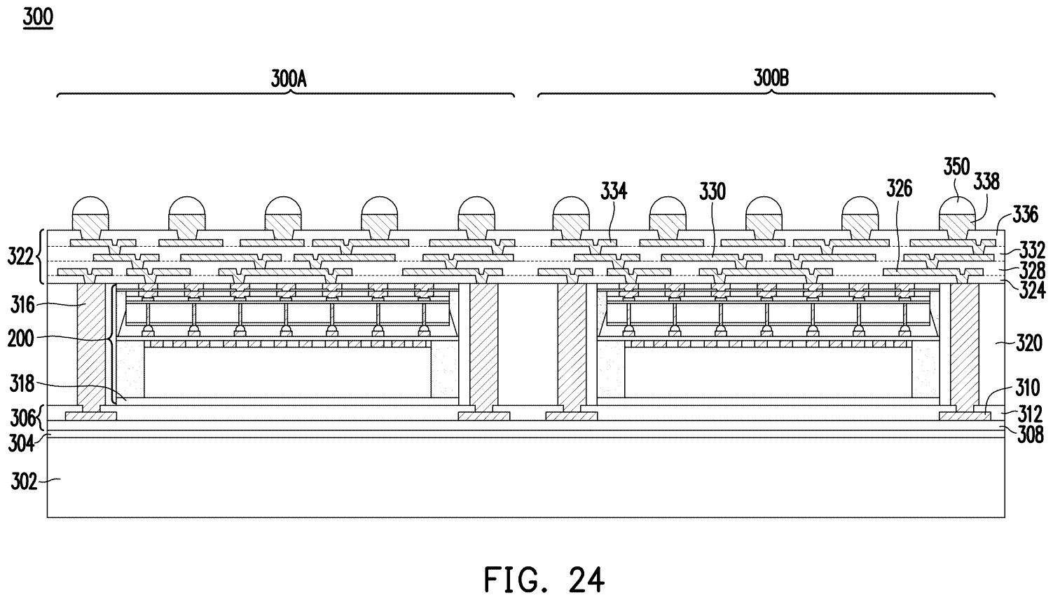

In FIG. 24, conductive connectors 350 are formed on the UBMs 338. The conductive connectors 350 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 350 may include a conductive material such as solder, copper, aluminum, gold, nickel, silver, palladium, tin, the like, or a combination thereof. In some embodiments, the conductive connectors 350 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 350 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

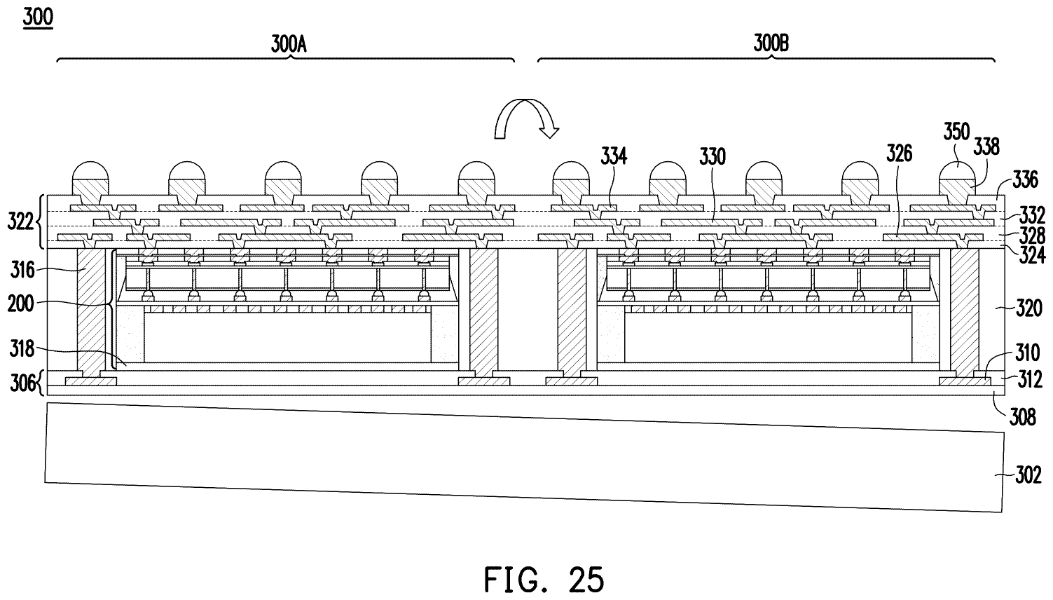

In FIG. 25, a carrier substrate de-bonding is performed to detach (or “de-bond”) the carrier substrate 302 from the back-side redistribution structure 306, e.g., the dielectric layer 308. In accordance with some embodiments, the de-bonding includes projecting a light such as a laser light or an UV light on the release layer 304 so that the release layer 304 decomposes under the heat of the light and the carrier substrate 302 can be removed. The structure is then flipped over and placed on a tape (not shown).

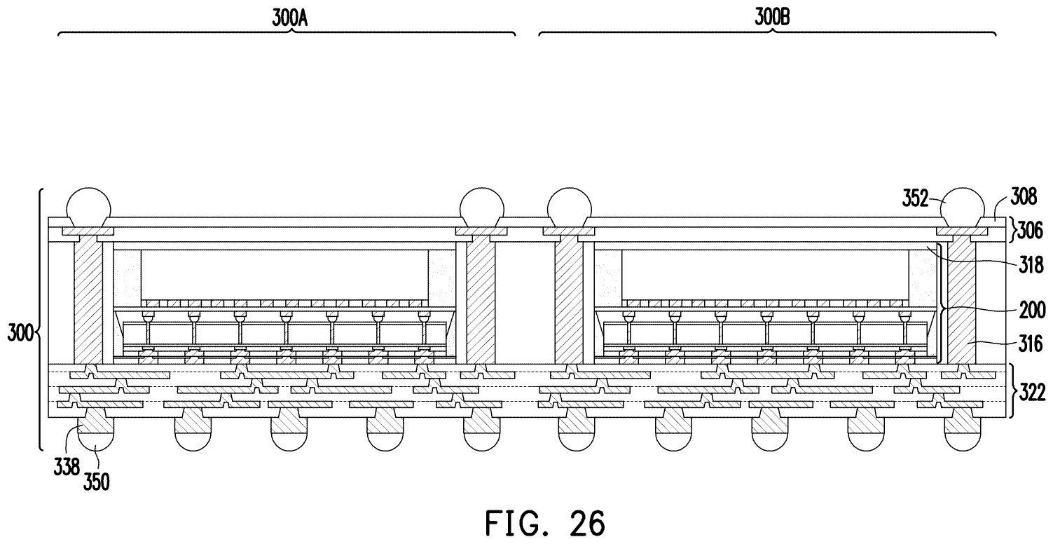

In FIG. 26, conductive connectors 352 are formed extending through the dielectric layer 308 to contact the metallization pattern 310. Openings are formed through the dielectric layer 308 to expose portions of the metallization pattern 310. The openings may be formed, for example, using laser drilling, etching, or the like. The conductive connectors 352 are formed in the openings. In some embodiments, the conductive connectors 352 comprise flux and are formed in a flux dipping process. In some embodiments, the conductive connectors 352 comprise a conductive paste such as solder paste, silver paste, or the like, and are dispensed in a printing process. In some embodiments, the conductive connectors 352 are formed in a manner similar to the conductive connectors 350, and may be formed of a similar material as the conductive connectors 350.

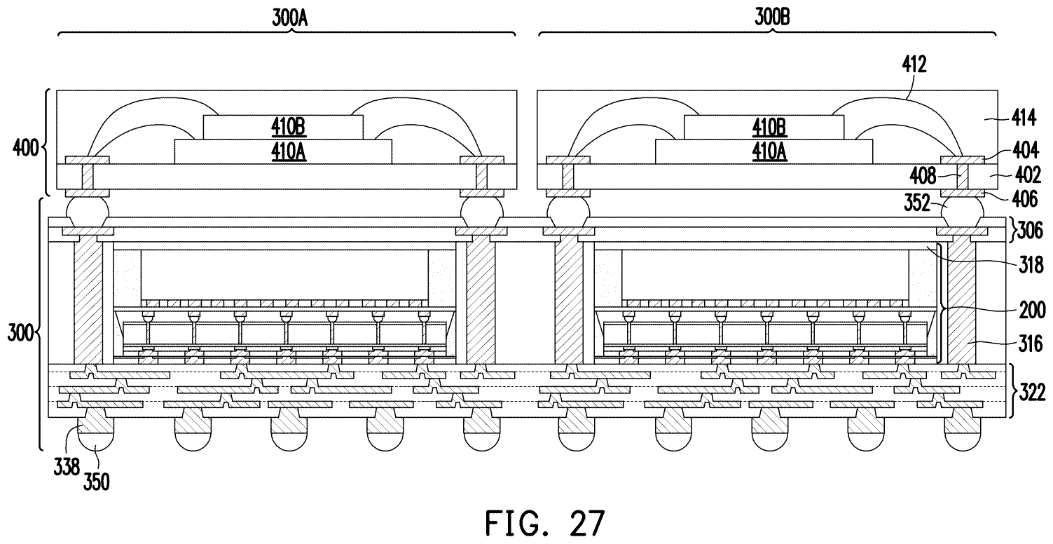

FIGS. 27 and 28 illustrate formation and implementation of device stacks, in accordance with some embodiments. The device stacks are formed from the integrated circuit packages formed in the package component 300. The device stacks may also be referred to as package-on-package (POP) structures.

In FIG. 27, package components 400 are coupled to the package component 300. One of the package components 400 is coupled in each of the package regions 300A and 300B to form an integrated circuit device stack in each region of the package component 300.

The package components 400 include, for example, a substrate 402 and one or more stacked dies 410 (e.g., 410A and 410B) coupled to the substrate 402. Although one set of stacked dies 410 (410A and 410B) is illustrated, in other embodiments, a plurality of stacked dies 410 (each having one or more stacked dies) may be disposed side-by-side coupled to a same surface of the substrate 402. The substrate 402 may be made of a semiconductor material such as silicon, germanium, diamond, or the like. In some embodiments, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate 402 may be a silicon-on-insulator (SOI) substrate. Generally, an SOI substrate includes a layer of a semiconductor material such as epitaxial silicon, germanium, silicon germanium, SOI, silicon germanium on insulator (SGOI), or combinations thereof. The substrate 402 is, in one alternative embodiment, based on an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for the substrate 402.

The substrate 402 may include active and passive devices (not shown). A wide variety of devices such as transistors, capacitors, resistors, combinations of these, and the like may be used to generate the structural and functional requirements of the design for the package components 400. The devices may be formed using any suitable methods.

The substrate 402 may also include metallization layers (not shown) and the conductive vias 408. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate 402 is substantially free of active and passive devices.

The substrate 402 may have bond pads 404 on a first side of the substrate 402 to couple to the stacked dies 410, and bond pads 406 on a second side of the substrate 402, the second side being opposite the first side of the substrate 402, to couple to the conductive connectors 352. In some embodiments, the bond pads 404 and 406 are formed by forming recesses (not shown) into dielectric layers (not shown) on the first and second sides of the substrate 402. The recesses may be formed to allow the bond pads 404 and 406 to be embedded into the dielectric layers. In other embodiments, the recesses are omitted as the bond pads 404 and 406 may be formed on the dielectric layer. In some embodiments, the bond pads 404 and 406 include a thin seed layer (not shown) made of copper, titanium, nickel, gold, palladium, the like, or a combination thereof. The conductive material of the bond pads 404 and 406 may be deposited over the thin seed layer. The conductive material may be formed by an electro-chemical plating process, an electroless plating process, CVD, atomic layer deposition (ALD), PVD, the like, or a combination thereof. In an embodiment, the conductive material of the bond pads 404 and 406 is copper, tungsten, aluminum, silver, gold, the like, or a combination thereof.

In some embodiments, the bond pads 404 and the bond pads 406 are UBMs that include three layers of conductive materials, such as a layer of titanium, a layer of copper, and a layer of nickel. Other arrangements of materials and layers, such as an arrangement of chrome/chrome-copper alloy/copper/gold, an arrangement of titanium/titanium tungsten/copper, or an arrangement of copper/nickel/gold, may be utilized for the formation of the bond pads 404 and 406. Any suitable materials or layers of material that may be used for the bond pads 404 and 406 are fully intended to be included within the scope of the current application. In some embodiments, the conductive vias 408 extend through the substrate 402 and couple at least one of the bond pads 404 to at least one of the bond pads 406.

In the illustrated embodiment, the stacked dies 410 are coupled to the substrate 402 by wire bonds 212, although other connections may be used, such as conductive bumps. In an embodiment, the stacked dies 410 are stacked memory dies. For example, the stacked dies 410 may be memory dies such as low-power (LP) double data rate (DDR) memory modules, such as LPDDR1, LPDDR2, LPDDR3, LPDDR4, or the like memory modules.

The stacked dies 410 and the wire bonds 412 may be encapsulated by a molding material 414. The molding material 414 may be molded on the stacked dies 410 and the wire bonds 412, for example, using compression molding. In some embodiments, the molding material 414 is a molding compound, a polymer, an epoxy, silicon oxide filler material, the like, or a combination thereof. A curing process may be performed to cure the molding material 414; the curing process may be a thermal curing, a UV curing, the like, or a combination thereof.

In some embodiments, the stacked dies 410 and the wire bonds 412 are buried in the molding material 414, and after the curing of the molding material 414, a planarization step, such as a grinding, is performed to remove excess portions of the molding material 414 and provide a substantially planar surface for the package components 400.

After the package components 400 are formed, the package components 400 are mechanically and electrically bonded to the package component 300 by way of the conductive connectors 352, the bond pads 406, and a metallization pattern of the back-side redistribution structure 306. In some embodiments, the stacked dies 410 may be coupled to the package components 200 through the wire bonds 412, the bond pads 404 and 406, the conductive vias 408, the conductive connectors 352, the back-side redistribution structure 306, the through vias 316, and the front-side redistribution structure 322.

In some embodiments, a solder resist (not shown) is formed on the side of the substrate 402 opposing the stacked dies 410. The conductive connectors 352 may be disposed in openings in the solder resist to be electrically and mechanically coupled to conductive features (e.g., the bond pads 406) in the substrate 402. The solder resist may be used to protect areas of the substrate 402 from external damage.

In some embodiments, the conductive connectors 352 have an epoxy flux (not shown) formed thereon before they are reflowed with at least some of the epoxy portion of the epoxy flux remaining after the package components 400 are attached to the package component 300.

In some embodiments, an underfill (not shown) is formed between the package component 300 and the package components 400, surrounding the conductive connectors 352. The underfill may reduce stress and protect the joints resulting from the reflowing of the conductive connectors 352. The underfill may be formed by a capillary flow process after the package components 400 are attached, or may be formed by a suitable deposition method before the package components 400 are attached. In embodiments where the epoxy flux is formed, it may act as the underfill.

In FIG. 28, a singulation process is performed by sawing along scribe line regions, e.g., between the first package region 300A and the second package region 300B. The sawing singulates the first package region 300A from the second package region 300B. The resulting, singulated device stack is from one of the first package region 300A or the second package region 300B. In some embodiments, the singulation process is performed after the package components 400 are coupled to the package component 300. In other embodiments (not shown), the singulation process is performed before the package components 400 are coupled to the package component 300, such as after the carrier substrate 302 is de-bonded and the conductive connectors 352 are formed.

Each singulated package component 300 may then be mounted to a package substrate 500 using the conductive connectors 350. The package substrate 500 includes a substrate core 502 and bond pads 504 over the substrate core 502. The substrate core 502 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate core 502 may be an SOI substrate. Generally, an SOI substrate includes a layer of a semiconductor material such as epitaxial silicon, germanium, silicon germanium, SOI, SGOI, or combinations thereof. The substrate core 502 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for substrate core 502.

The substrate core 502 may include active and passive devices (not shown). A wide variety of devices such as transistors, capacitors, resistors, combinations of these, and the like may be used to generate the structural and functional requirements of the design for the device stack. The devices may be formed using any suitable methods.

The substrate core 502 may also include metallization layers and vias (not shown), with the bond pads 504 being physically and/or electrically coupled to the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate core 502 is substantially free of active and passive devices.

In some embodiments, the conductive connectors 350 are reflowed to attach the package component 300 to the bond pads 504. The conductive connectors 350 electrically and/or physically couple the package substrate 500, including metallization layers in the substrate core 502, to the package component 300. In some embodiments, a solder resist 506 is formed on the substrate core 502. The conductive connectors 350 may be disposed in openings in the solder resist 506 to be electrically and mechanically coupled to the bond pads 504. The solder resist 506 may be used to protect areas of the substrate core 502 from external damage.

The conductive connectors 350 may have an epoxy flux (not shown) formed thereon before they are reflowed with at least some of the epoxy portion of the epoxy flux remaining after the package component 300 is attached to the package substrate 500. This remaining epoxy portion may act as an underfill to reduce stress and protect the joints resulting from reflowing the conductive connectors 350. In some embodiments, an underfill 508 may be formed between the package component 300 and the package substrate 500 and surrounding the conductive connectors 350. The underfill 508 may be formed by a capillary flow process after the package component 300 is attached or may be formed by a suitable deposition method before the package component 300 is attached.

In some embodiments, passive devices (e.g., surface mount devices (SMDs), not shown) may also be attached to the package component 300 (e.g., to the UBMs 338) or to the package substrate 500 (e.g., to the bond pads 504). For example, the passive devices may be bonded to a same surface of the package component 300 or the package substrate 500 as the conductive connectors 350. The passive devices may be attached to the package component 300 prior to mounting the package component 300 on the package substrate 500, or may be attached to the package substrate 500 prior to or after mounting the package component 300 on the package substrate 500.

The package component 300 may be implemented in other device stacks. For example, a PoP structure is shown, but the package component 300 may also be implemented in a Flip Chip Ball Grid Array (FCBGA) package. In such embodiments, the package component 300 is mounted to a substrate such as the package substrate 500, but the package component 400 is omitted. Instead, a lid or heat spreader may be attached to the package component 300. When the package component 400 is omitted, the back-side redistribution structure 306 and through vias 316 may also be omitted.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments may achieve advantages. Embodiments discussed herein may be discussed in a specific context, namely a via or connector structure that can be integrated into a device (e.g., a chip or die) or a package (e.g., an integrated fan-out (InFO) package structure). The via or connector structure includes stacked vias and multiple passivation layers to allow for the ability to test the dies and chips of the package structure while also allowing for a lower chip package interaction (CPI) risk of the package structure. For example, the stacked vias and multiple polymer layers allow for each of the chips of a chiplet structure to be tested and be known good dies (KGDs) while providing protection for the chips during and after the testing.

An embodiment is a method including forming a first die, the forming including forming through vias in a first substrate. The method also includes forming a first redistribution structure over the through vias and the first substrate, the first redistribution structure being electrically coupled to the through vias. The method also includes forming a first set of die connectors over and electrically coupled to the first redistribution structure, the first set of die connectors being on a first side of the first substrate. The method also includes thinning a second side of the first substrate, the thinning exposing the through vias. The method also includes bonding the first die to a second die. The method also includes encapsulating the first die with a first encapsulant. The method also includes forming a second set of die connectors over and electrically coupled to the first set of die connectors, the first and second sets of die connectors forming stacked die connectors.

Embodiments may include one or more of the following features. The method further including forming a first dielectric layer on the first set of die connectors and the first redistribution structure, the first dielectric layer having sidewalls coterminous with sidewalls of the first redistribution structure, the first set of die connectors being in the first dielectric layer. The method further including forming a second dielectric layer on the first set of die connectors, the first dielectric layer, and the first encapsulant, the second set of die connectors being in the second dielectric layer. The second dielectric layer has sidewalls coterminous with sidewalls of the first encapsulant. The first and second dielectric layers are polymer layers. The first and second dielectric layers include different materials. The first encapsulant contacts the sidewalls of the first dielectric layer and the first redistribution structure. The first set of die connectors have different widths than the second set of die connectors. The first set of die connectors are wider than the second set of die connectors. The method further including forming conductive features over a carrier substrate, attaching the bonded first and second dies to the carrier substrate adjacent the conductive features, encapsulating the bonded first and second dies and the conductive features in a second encapsulant, and forming a second redistribution structure over the bonded first and second dies, the conductive features, and the second encapsulant, the second redistribution structure being electrically coupled to the second set of die connectors and the conductive features. The method further including forming conductive connectors over and electrically coupled to the second redistribution structure, removing the carrier substrate, and bonding the conductive connectors to a package substrate.

An embodiment is a method including encapsulating a first integrated circuit die in a first encapsulant, the first integrated circuit die including a first substrate and active devices. The method also includes forming a first redistribution structure over the first integrated circuit die and the first encapsulant. The method also includes forming a second integrated circuit die including a second substrate and active devices, forming the second integrated circuit die including forming through vias in the second substrate. The method also includes forming a second redistribution structure over the through vias and the second substrate, the second redistribution structure being electrically coupled to the through vias. The method also includes forming a first set of conductive vias over and electrically coupled to the second redistribution structure, the first set of conductive vias being on a first side of the second substrate. The method also includes thinning a second side of the second substrate, the thinning exposing the through vias. The method also includes bonding the first integrated circuit die to the second integrated circuit die. The method also includes encapsulating the second integrated circuit die with a second encapsulant. The method also includes forming a second set of conductive vias over and electrically coupled to the first set of conductive vias, the first and second sets of conductive vias forming stacked conductive vias.

Embodiments may include one or more of the following features. The method further including forming a first polymer layer on the first set of conductive vias and the second redistribution structure, the first polymer layer having sidewalls coterminous with sidewalls of the second redistribution structure, the first set of conductive vias being in the first polymer layer. The method further including forming a second polymer layer on the first set of conductive vias, the first polymer layer, and the second encapsulant, the second set of conductive vias being in the second polymer layer. The second polymer layer has sidewalls coterminous with sidewalls of the second encapsulant. The method further including forming conductive features over a carrier substrate, attaching the bonded first and second integrated circuit dies to the carrier substrate adjacent the conductive features, encapsulating the bonded first and second integrated circuit dies and the conductive features in a third encapsulant, the third encapsulant contacting the first and second encapsulants, and forming a third redistribution structure over the second integrated circuit die, the conductive features, and the third encapsulant, the third redistribution structure being electrically coupled to the second set of conductive vias and the conductive features.

An embodiment is a structure including a first integrated circuit die bonded to a second integrated circuit die, the first integrated circuit die being in a first encapsulant, the first integrated circuit die including a first substrate. The structure also includes active devices. The structure also includes through vias in the first substrate. The structure also includes a first redistribution structure over the through vias and the first substrate, the first redistribution structure being electrically coupled to the through vias. The structure also includes a first set of conductive vias over and electrically coupled to the first redistribution structure, the first set of conductive vias being on a first side of the first substrate. The structure also includes a second set of conductive vias over and electrically coupled to the first set of conductive vias, the first and second sets of conductive vias forming stacked conductive vias.

Embodiments may include one or more of the following features. The structure further including a second encapsulant on the second integrated circuit die, the second integrated circuit die including a second substrate and active devices, and a second redistribution structure over the second integrated circuit die and the first encapsulant. The structure further including a first polymer layer on the first set of conductive vias and the second redistribution structure, the first polymer layer having sidewalls coterminous with sidewalls of the second redistribution structure, the first set of conductive vias being in the first polymer layer, and a second polymer layer on the first set of conductive vias, the first polymer layer, and the second encapsulant, the second set of conductive vias being in the second polymer layer, the second polymer layer has sidewalls coterminous with sidewalls of the second encapsulant. The first set of conductive vias have different widths than the second set of conductive vias.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first die;
forming a second die comprising:
forming through vias in a first substrate;
forming a first redistribution structure over the through vias and the first substrate, the first redistribution structure being electrically coupled to the through vias; and
forming a first set of die connectors over and electrically coupled to the first redistribution structure, the first set of die connectors being on a first side of the first substrate;
bonding the first die to the second die;
encapsulating the first die with a first encapsulant; and
forming a second set of die connectors over and electrically coupled to the first set of die connectors, the first and second sets of die connectors forming stacked die connectors.

2. The method of claim 1, wherein the first die comprises a logic die.

3. The method of claim 1, wherein the second die comprises a memory die.

4. The method of claim 1, further comprising forming a second redistribution structure over the first encapsulant and electrically coupled to the stacked die connectors.

5. The method of claim 4, wherein the second redistribution structure comprises three or more metallization layers.

6. The method of claim 1, wherein the first set of die connectors comprises copper pillars.

7. The method of claim 1, wherein the stacked die connectors have a width ratio of the second set to the first set in a range from 0.8 to 2.

8. A semiconductor device comprising:
a lower package including:
a first die;
a second die having through vias in a substrate, the first die being bonded to the second die; and
a first redistribution structure over the through vias and the substrate, the first redistribution structure being electrically coupled to the through vias;
a first encapsulant surrounding the first die and the second die;
a second redistribution structure over the first encapsulant;
an upper package including:
a third die; and
a second encapsulant surrounding the third die;
stacked connectors between and electrically coupling the second redistribution structure of the lower package and the upper package; and
an underfill material between the lower package and the upper package.

9. The semiconductor device of claim 8, wherein the first die comprises a logic die and the second die comprises a memory die.

10. The semiconductor device of claim 8, wherein the third die comprises a memory die.

11. The semiconductor device of claim 8, wherein the stacked connectors comprise alternating conductive and dielectric layers.

12. The semiconductor device of claim 8, wherein the stacked connectors comprise at least three alternating conductive and dielectric layers.

13. The semiconductor device of claim 8, wherein the second redistribution structure comprises four or more metallization layers.

14. The semiconductor device of claim 8, further comprising conductive connectors electrically coupling the lower package to a package substrate.

15. A method comprising:
forming a first die;
forming a second die comprising:
forming through vias in a substrate;
forming a first redistribution structure over the through vias and the substrate, the first redistribution structure being electrically coupled to the through vias; and
forming a first set of die connectors over and electrically coupled to the first redistribution structure;
bonding the first die to the second die;
encapsulating the first die and the second die with an encapsulant;
forming a second set of die connectors over and electrically coupled to the first set of die connectors, the first and second sets of die connectors forming stacked die connectors;
forming a second redistribution structure over the encapsulant and electrically coupled to the stacked die connectors;
singulating through the encapsulant and the second redistribution structure to form an individual package; and
mounting the individual package to a package substrate using conductive connectors, the conductive connectors being electrically coupled to the second redistribution structure.

16. The method of claim 15, further comprising forming a dielectric layer between the first set of die connectors and the second set of die connectors.

17. The method of claim 16, wherein the dielectric layer comprises a polymer.

18. The method of claim 15, wherein the stacked die connectors have a width in the second set of die connectors that is larger than a width in the first set of die connectors.

19. The method of claim 15, wherein the second redistribution structure comprises five metallization layers.

20. The method of claim 15, further comprising forming passive devices on the second redistribution structure.
